(19) United States
(12) Patent Application Publication
(10) Pub. No.: US 2026/0213722 A1
(43) Pub. Date: Jul. 23, 2026

(54) Tuning The Frequency-Temperature Response of MEMS Resonators Using Composite Eigenmodes

(71) Applicant: Stathera IP Holdings Inc., Montreal (CA)

(72) Inventors: Christophe Sabourin, Montreal (CA); Anosh Daruwalla, Montreal (CA)

(21) Appl. No.: 19/140,804

(22) PCT Filed: Dec. 20, 2023
(86) PCT No.: PCT/CA2023/051722

§ 371 Date: Jun. 18, 2025

Related U.S. Application Data
(60) Provisional application No. 63/433,938, filed on Dec. 20, 2022.

(51) Int. Cl. H03H 3/04; H03H 3/02; H03H 9/02; H03H 9/15; H03H 9/24

(52) U.S. Cl. CPC H03H 3/04; H03H 9/02244; H03H 9/15; H03H 9/2431; H03H 9/2436; H03H 2003/027; H03H 2003/0407; H03H 2009/02503; H03H 2009/155

(57) ABSTRACT

A MEMS resonator device is provided. The MEMS resonator device comprises a support structure, a composite eigenmode resonator element, an anchor, a driving electrode and a sense electrode. The composite eigenmode resonator element includes at least two sub-regions. Each of the at least two sub-regions in isolation resonate with an eigenmode from a set of at least two eigenmodes, and have an Nth order temperature coefficient of frequency (TCFNfc). A first and second sub-region in isolation resonate with a first and second eigenmode from the set of at least two eigenmodes and have a particular dopant type, a particular doping concentration and a first and second orientation with respect to the crystal axis. The anchor couples the composite eigenmode resonator element to the support structure. The driving electrode actuates the composite eigenmode resonator element. The sense electrode senses the composite eigenmode resonator element.

### TECHNICAL FIELD

The present disclosure relates to the field of microelectromechanical systems (MEMS) resonators.

### BACKGROUND

The advent of Internet of Things (IoT) has given rise to a myriad of sensor-based devices used in wearables, smartphones, and remote sensing for industrial and consumer applications. Timing references are ubiquitous in these devices and help provide signals used to keep track of time, synchronize events in digital integrated circuits (ICs), and process signals. High-accuracy microelectromechanical systems (MEMS) resonators may be desirable for such high-performance electronic applications.

### SUMMARY

It is an aim of the present disclosure to achieve an improved temperature compensated MEMS device, such as a resonator.

According to the present disclosure, a MEMS resonator device is provided. The MEMS resonator device comprises: a support structure; a composite eigenmode resonator element comprising at least two sub-regions, wherein each of the at least two sub-regions in isolation is configured to resonate with a respective eigenmode from a set of at least two eigenmodes and has a respective Nth order temperature coefficient of frequency (TCFNₖ), wherein the at least two sub-regions includes a first sub-region and a second sub-region, wherein the first sub-region in isolation is configured to resonate with a first eigenmode from the set of at least two eigenmodes and has a particular dopant type, a particular doping concentration, a first orientation with respect to the crystal axis, and a first TCFNₖ, wherein the second sub-region in isolation is configured to resonate with a second eigenmode from the set of at least two eigenmodes and has the particular dopant type, the particular doping concentration, a second orientation with respect to the crystal axis, and a second TCFNₖ, and wherein either (i) the first TCFNₖ is greater than a desired Nth order temperature coefficient of frequency of the composite eigenmode resonator element (TCFN_{desired}) and the second TCFNₖ is less than TCFN_{desired} or (ii) the first TCFNₖ is less than TCFN_{desired} and the second TCFNₖ is greater than TCFN_{desired}; at least one anchor coupling the composite eigenmode resonator element to the support structure; at least one driving electrode for actuation of the composite eigenmode resonator element; and at least one sense electrode for sensing of the composite eigenmode resonator element.

According to the present disclosure, a method for designing a MEMS resonator device is provided. The method comprises: selecting a desired Nth order temperature coefficient of frequency (TCFN_{desired}) for a composite eigenmode resonator element, wherein the composite eigenmode resonator element comprises at least two sub-regions, wherein each of the at least two sub-regions is configured to resonate with a respective eigenmode from a set of at least two eigenmodes and is configured to have a respective Nth order temperature coefficient of frequency (TCFNₖ); providing a first sub-region of the at least two sub-regions, wherein the first sub-region in isolation is configured to resonate with a first eigenmode from the set of at least two eigenmodes and has a particular dopant type, a particular doping concentration, and a first orientation with respect to the crystal axis, and wherein the first sub-region has a first TCFNₖ; providing a second sub-region of the at least two sub-regions, wherein the second sub-region in isolation is configured to resonate with a second eigenmode from the set of at least two eigenmodes and has the particular dopant type, the particular doping concentration, and a second orientation with respect to the crystal axis, and wherein the second sub-region has a second TCFNₖ; determining, for the composite eigenmode resonator element comprising the at least two sub-regions, an Nth order temperature coefficient of frequency of (TCFNₜₒₜₐₗ); and tuning TCFNₜₒₜₐₗ such that it is approximately equal to TCFN_{desired}, wherein tuning TCFNₜₒₜₐₗ comprises altering at least one of the first or second TCFNₖ such that either (i) the first TCFNₖ is greater than TCFN_{desired} and the second TCFNₖ is less than TCFN_{desired} or (ii) the first TCFNₖ is less than TCFN_{desired} and the second TCFNₖ is greater than TCFN_{desired}.

### BRIEF DESCRIPTION OF THE DRAWINGS

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A depicts an example cross-section of a composite eigenmode resonator device which is capacitively transduced.

FIG. 1B depicts an example cross-section of a composite eigenmode resonator device which is piezoelectrically transduced.

FIG. 2 depicts the frequency shift as a function of temperature of a composite eigenmode resonator element.

FIG. 3A depicts the predictable response of TCFₜₒₜₐₗ at different doping concentrations, with different dopant types, for a wineglass/length-extensional composite eigenmode in the <100> silicon lattice orientation.

FIG. 3B depicts the predictable response of TCF1ₜₒₜₐₗ at different doping concentrations, with different dopant types, for a wineglass/length-extensional composite eigenmode in the <110> silicon lattice orientation.

FIG. 3C depicts the predictable response of TCF2ₜₒₜₐₗ at different doping concentrations, with different dopant types, for a wineglass/length-extensional composite eigenmode in the <100> silicon lattice orientation.

FIG. 3D depicts the predictable response of TCF2ₜₒₜₐₗ at different doping concentrations, with different dopant types, for a wineglass/length-extensional composite eigenmode in the <110> silicon lattice orientation.

FIG. 4 depicts multiple examples of composite eigenmode resonator elements.

FIG. 5 depicts a method to tune the temperature-induced frequency response of a composite eigenmode resonator element containing two sub-regions.

FIG. 6A depicts example results of effective mass tuning a face-shear/square-extensional composite eigenmode by adding or removing sub-regions resonating with a particular eigenmode.

FIG. 6B depicts example results of effective mass tuning a face-shear/square-extensional composite eigenmode by adding or removing sub-regions resonating with a particular eigenmode.

FIG. 6C depicts example results of effective mass tuning a square-extensional/Lamé composite eigenmode by adding or removing sub-regions resonating with a particular eigenmode.

FIG. 6D depicts example results of effective mass tuning a square-extensional/length-extensional composite eigenmode by adding or removing sub-regions resonating with a particular eigenmode.

FIG. 6E depicts example results of effective mass tuning a Lamé/Nth order annulus composite eigenmode by adding or removing sub-regions resonating with a particular eigenmode.

FIG. 6F depicts example results of effective mass tuning a face-shear/length-extensional composite eigenmode by adding or removing sub-regions resonating with a particular eigenmode.

FIG. 6G depicts example results of effective mass tuning a wineglass/length-extensional composite eigenmode by adding or removing sub-regions resonating with a particular eigenmode.

FIG. 6H depicts example results of effective mass tuning a breathing/face-shear composite eigenmode by adding or removing sub-regions resonating with a particular eigenmode.

FIG. 7A depicts example results of effective mass tuning a Lamé/square-extensional composite eigenmode by both adding or removing sub-regions resonating with a particular eigenmode and modifying the size of a sub-region resonating with the particular eigenmode, without altering the resonance frequency of the particular eigenmode.

FIG. 7B depicts example results of effective mass tuning a wineglass/length-extensional composite eigenmode composite eigenmode by both adding or removing sub-regions resonating with a particular eigenmode and modifying the size of a sub-region resonating with the particular eigenmode, without altering the resonance frequency of the particular eigenmode.

FIG. 8A depicts example results of resonance frequency tuning the TCFNₜₒₜₐₗ of a square-extensional/Lamé composite eigenmode.

FIG. 8B depicts example results of resonance frequency tuning the TCFNₜₒₜₐₗ of a square-extensional/length-extensional composite eigenmode.

FIG. 8C depicts example results of resonance frequency tuning the TCFNₜₒₜₐₗ of a breathing/face-shear composite eigenmode.

FIG. 9A depicts example results of tuning TCF1ₜₒₜₐₗ by adding cavities to one or more sub-regions of a composite eigenmode resonator element.

FIG. 9B depicts example results of tuning TCF2ₜₒₜₐₗ by adding cavities to one or more sub-regions of a composite eigenmode resonator element.

### DETAILED DESCRIPTION

### I. Overview

While quartz crystal oscillators have been the foundation of timing and frequency reference applications for the past century, the rapid development of sensor-based electronics has highlighted certain limitations of this technology, such as power consumption, robustness, size, and CMOS compatibility. Over the past two decades, MEMS resonators fabricated with silicon have drawn significant attention due to their small size, low cost, and integration compatibility. However, MEMS resonators still have not been able to replace their quartz counterparts in multiple applications.

A limitation of MEMS resonators that has curbed widespread adoption is the lack of temperature stability as compared to quartz. Silicon MEMS resonators have an inherent first order temperature-induced frequency drift of approximately-30 ppm/° C., resulting in a temperature stability of approximately 3,750 ppm over the industrial temperature range of-40° C. to 85° C. In comparison, AT-cut quartz resonators have a temperature stability of approximately 20 ppm over the industrial temperature range of operation. There have been several attempts made to overcome these temperature-induced frequency drifts, such as methods involving the use of highly doped silicon substrates and composite materials. Temperature-induced frequency drift compensation with highly doped silicon substrates may be impractical for certain applications as it may provide only first order or second order compensation of the temperature-induced frequency drift at particular doping concentrations, which may be difficult to source from foundries. Additionally, temperature-induced frequency drift compensation with composite materials may face issues with aging, increased processing complexity and decreased quality (Q)-factor.

The change in frequency with respect to temperature of a MEMS resonator is given by the equation:

$$f ( T ) = {f}_{0} [ TCF 1 * ( Δ T ) + TCF 2 * {( Δ T )}^{2} + … ] \qquad ( 1 )$$

where f₀ is the resonance frequency of the MEMS resonator at a reference temperature, ΔT is the deviation from the reference temperature, TCF1 is the first order temperature coefficient of frequency, and TCF2 is the second order temperature coefficient of frequency. For single crystal silicon the value of TCF2 is typically within the range of −25 to −80 ppb/° C.² depending on the dopant type and concentration, which can result in a temperature-induced frequency drift of approximately 200-400 ppm over the industrial temperature range. While this second order temperature-induced frequency drift is relatively small compared to the uncompensated temperature-induced frequency drift of silicon (−3,750 ppm based on-30 ppm/° C.), it is still significantly worse than the typical temperature-induced frequency drift that AT-cut quartz crystals can provide. As such, it may be desirable to further reduce the temperature-induced frequency drift of fabricated silicon MEMS resonators in order enable their wide adoption in the timing market.

While it is possible to use active temperature compensation techniques to minimize temperature-induced frequency drifts, such techniques may place a significant burden on the system in terms of power consumption, circuit size, and circuit complexity. Hence it may be beneficial to find methods to passively compensate for temperature-induced frequency drifts in fabricated silicon MEMS resonators.

Various techniques have been used previously to passively compensate for temperature-induced frequency drifts. For example, fabricating MEMS resonators which include a secondary material such as silicon dioxide (SiO₂) is a well-established technique. SiO₂ is known to have a large positive TCF1 (approximately 85 ppm/° C.), and due to its compatibility with silicon, it can be incorporated in silicon MEMS resonators to counterbalance the negative TCF1 of silicon. Within the industrial temperature range, total temperature-induced frequency drifts as low as sub-100 ppm have been achieved by this method. In the same temperature range, for smaller devices operating at higher frequencies (such as thin-film bulk acoustic resonators), temperature-induced frequency drifts as small as 3 ppm have been shown using this technique. However, one must take into consideration TCF2 effects of the oxide, which are not well documented in literature and difficult to measure due to its small scale, as well as the loss in resonator Q-factor related to thermoelastic damping and/or surface losses. Moreover, this technique increases complexity in manufacturing and has reliability issues due to film-stresses, which lead to long-term aging issues.

Another example of an existing passive compensation technique involves fabricating MEMS resonators using highly-doped silicon substrates. This is a well-established technique as the TCF1 of particular eigenmodes change with doping concentration. For example, within the industrial temperature range of −40° C. to 85° C., it is possible to limit the temperature-induced frequency drift of MEMS resonators operating in the Lamé mode to the range of 200-400 ppm using highly doped silicon substrates. However, even when TCF1 becomes zero, there may still be a significant amount of temperature-induced frequency drift caused by higher order temperature coefficients of frequency.

### II. Overview of Passively Compensating Temperature-Induced Frequency Drift with Composite Eigenmode Resonators

A composite eigenmode resonator element 104 is a mechanically vibrating resonator element that exhibits at least two different eigenmodes at resonance. These eigenmodes will occur on distinct areas of the composite eigenmode resonator element 104, further referred to as sub-regions. Thus, a ‘sub-region’ is a contiguous region resonating with a particular eigenmode, which may be connected to other sub-regions via a contact region significantly smaller than the sub-region. Composite eigenmode resonator elements 104 may be useful when designing MEMS resonators as they have a predictable and tunable temperature-induced frequency drift response. The Nth order temperature coefficient of frequency of a composite eigenmode resonator element 104 (TCFNₜₒₜₐₗ) can be calculated using a weighted average of the TCFN of the eigenmode exhibited by each respective sub-region in isolation (TCFNₖ). Herein, ‘eigenmode exhibited by each respective sub-region in isolation’ refers to the eigenmode exhibited by each respective sub-region when it has not been connected to another sub-region via a contact region. It is thus possible to design a composite eigenmode resonator element 104 with a specific TCFNₜₒₜₐₗ value using a combination of eigenmodes. Typically, each respective sub-region in isolation is selected from a set of standard geometries, including but not limited to (i) a square plate, (ii) a disk, (iii) a bar or (iv) an annulus. The TCFNₜₒₜₐₗ of any composite eigenmode resonator element 104 can be calculated using the following equation:

$$T C F {N}_{t o t a l} = {\sum }_{k = 1}^{n} [ {meff}_{k} * {TCFN}_{k} ] / {meff}_{t o t a l} \qquad ( 2 )$$

where n is the total number sub-regions, meffₖ is the effective mass of the kth sub-region in isolation, and meffₜₒₜₐₗ is the effective mass of the composite eigenmode resonator element 104. TCFNₖ may be calculated using analytical or simulation-based approaches now known or later developed. It is important to note that any order temperature coefficients of frequency of the composite eigenmode resonator element 104 can be calculated using a weighted average of the TCFNₖ of the eigenmode exhibited by each respective sub-region in isolation, though it may be most common to calculate the first order and second order temperature coefficient of frequency.

Effective mass is a quantitative measure of a given region's inertia with respect to resonance. It can be calculated using the following expression:

$${meff}_{k} = ρ {\int \int \int }_{{V}_{k}} \frac{[ {{d}_{k} ( x , y , z )}^{2} ]}{{A}_{t o t a l}} dx dy dz \qquad ( 3 )$$

where ρ is the density of the sub-region volume Vₖ, dₖ is the displacement field of the eigenmode in sub-region k in isolation, and Aₜₒₜₐₗ is the maximum displacement amplitude over the entire composite eigenmode resonator element 104. Plainly, the effective mass of a sub-region is dependent on the maximum displacement amplitude of the entire composite eigenmode resonator element 104. Effective mass is the weighing parameter in Equation 2 as it incorporates both the size differences and relative displacement amplitudes of the n sub-regions.

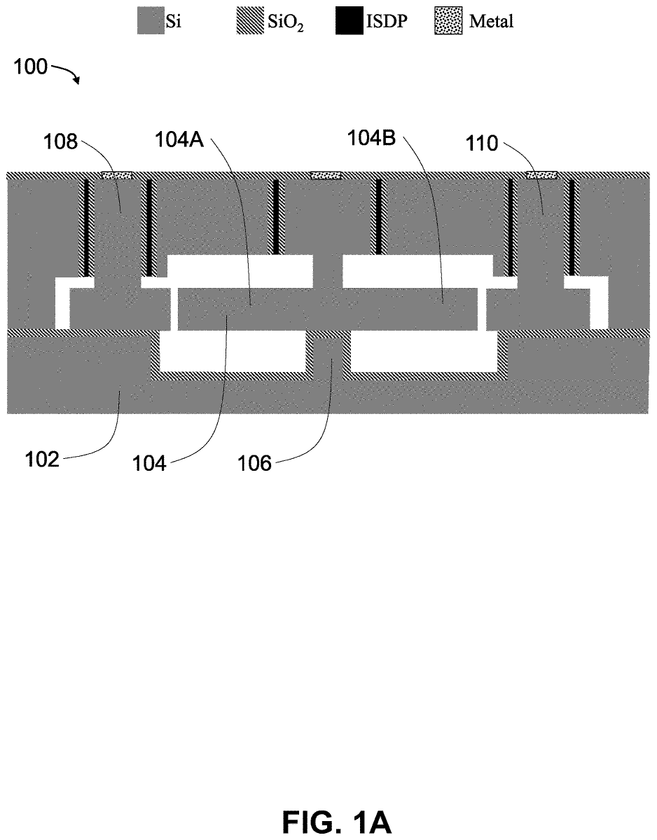

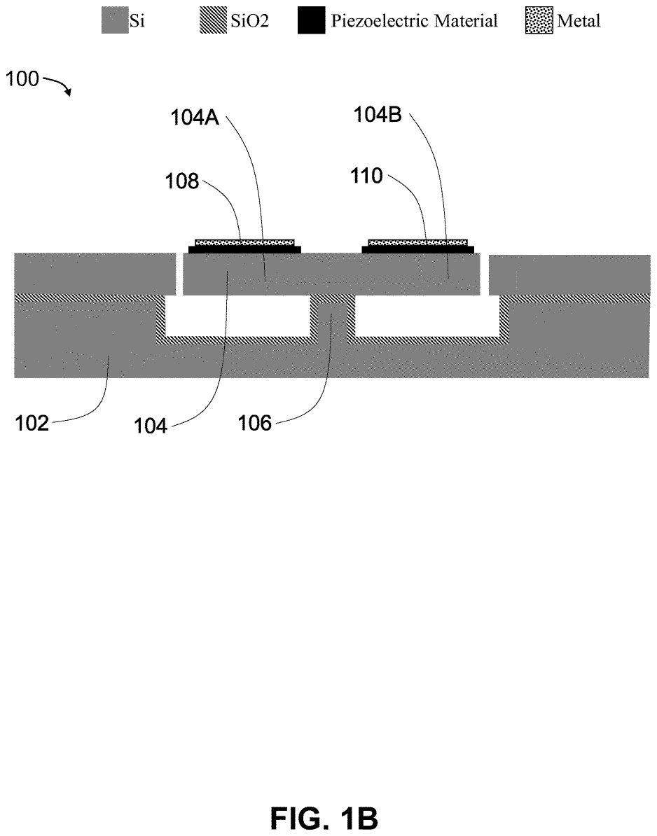

FIG. 1A depicts an example cross-section of a composite eigenmode resonator device 100 which is capacitively transduced. The composite eigenmode resonator device includes a support structure 102, a composite eigenmode resonator element 104, at least one anchor 106, at least one driving electrode 108, and at least one sense electrode 110. The composite eigenmode resonator element 104 includes at least two sub-regions. Each of the at least two sub-regions in isolation is configured to resonate with a respective eigenmode from a set of at least two eigenmodes and has a respective TCFNₖ. The at least two sub-regions includes a first sub-region 104A and a second sub-region 104B. The first sub-region 104A in isolation is configured to resonate with a first eigenmode from the set of at least two eigenmodes and has a particular dopant type, a particular doping concentration, a first orientation with respect to the crystal axis, and a first TCFNₖ. The second sub-region 104B in isolation is configured to resonate with a second eigenmode from the set of at least two eigenmodes and has the particular dopant type, the particular doping concentration, a second orientation with respect to the crystal axis, and a second TCFNₖ. Either (i) the first TCFNₖ>a desired Nth order temperature coefficient of frequency of the composite eigenmode resonator element 104 (TCFN_{desired}) and the second TCFNₖ<TCFN_{desired} or (ii) the first TCFNₖ<TCFN_{desired} and the second TCFNₖ>TCFN_{desired}. The at least one anchor 106 couples the composite eigenmode resonator element 104 to the support structure 102. The at least one driving electrode 108 actuates the composite eigenmode resonator element 104. The at least one sense electrode 110 senses the composite eigenmode resonator element 104.

FIG. 1B depicts an example cross-section of a composite eigenmode resonator device 100 which is piezoelectrically transduced. It is important to note that the addition of piezoelectric electrodes, such as the at least one driving electrode 108 and the at least one sense electrode 110, will have a minimal effect on TCFNₜₒₜₐₗ.

In some embodiments, the composite eigenmode resonator device 100 is either (i) capacitively transduced or (ii) piezoelectrically transduced.

In some embodiments, each of the at least two sub-regions are connected by a contact region to at least one other sub-region, wherein the contact region extends from points of maximum displacement amplitude.

In some additional embodiments, each of the at least two sub-regions are connected to at least one other sub-region by a contact region, and the contact region is minimized such that the modal distortions due to non-ideal coupling of the at least two sub-regions are minimized.

In some additional embodiments, the contact region further comprises a bar, and wherein the volume of the bar is less than 5% of the volume of the composite eigenmode resonator element.

In some embodiments, the at least two sub-regions further comprise a third sub-region, wherein the third sub-region in isolation resonates with the first eigenmode from the set of at least two eigenmodes and has the particular dopant type, the particular doping concentration, the first orientation with respect to the crystal axis, and the first TCFNₖ.

In some additional embodiments, the at least two sub-regions further comprise a fourth sub-region and a fifth sub-region, wherein both the fourth sub-region in isolation and the fifth sub-region in isolation resonate with the first eigenmode from the set of at least two eigenmodes and have the particular dopant type, the particular doping concentration, the first orientation with respect to the crystal axis, and the first TCFNₖ.

In some additional embodiments, the at least two sub-regions further comprise a sixth sub-region, a seventh sub-region, an eighth sub-region, and a ninth sub-region, wherein the sixth sub-region in isolation, the seventh sub-region in isolation, the eighth sub-region in isolation, and the ninth sub-region in isolation resonate with the first eigenmode from the set of at least two eigenmodes and have the particular dopant type, the particular doping concentration, the first orientation with respect to the crystal axis, and the first TCFNₖ.

In some additional embodiments, the at least two sub-regions further comprise a set of 4N+1 sub-regions, where Nis any integer greater than 2. Each sub-region in the 4N sub-regions of the set of 4N+1 sub-regions in isolation resonates with the first eigenmode from the set of at least two eigenmodes and has the particular dopant type, the particular doping concentration, the first orientation with respect to the crystal axis, and the first TCFNₖ. The remaining sub-region (i.e., the +1 sub-region in the set of 4N+1 sub-regions) in isolation resonates with the second eigenmode from the set of at least two eigenmodes and has the particular dopant type, the particular doping concentration, the second orientation with respect to the crystal axis, and the second TCFNₖ. The remaining sub-region may be placed at the center of the set of 4N+1 sub-regions, and the 4N sub-regions of the 4N+1 sub-regions may extend symmetrically from the points of maximum displacement of the remaining sub-region placed at the center.

In some embodiments, the respective resonance frequencies in isolation of the eigenmodes from the set of at least two eigenmodes are approximately equal. Herein and throughout this disclosure, ‘respective resonance frequencies in isolation are approximately equal’ means it is sufficient to reduce the difference between the resonance frequencies in isolation to be as close to zero as is practically possible. In some embodiments, this may involve reducing the difference to be less than 1 GHz. In other embodiments, this may involve reducing the difference to be less than 1 MHz. Still in other embodiments, this may involve reducing the difference to be less than 1 kHz. Still in other embodiments, this may involve reducing the difference between the resonance frequencies in isolation to be less than 1% of the resonance frequency of the composite eigenmode resonator element 104.

In some embodiments, the set of at least two eigenmodes comprises two or more eigenmodes selected from the group consisting of (i) Lamé, (ii) face-shear, (iii) square-extensional, (iv) width-extensional, (v) length-extensional, (vi) Nth order annulus, (vii) breathing, (viii) wineglass, and (ix) higher order Lamé eigenmodes.

In some embodiments, the TCFNₖS of the at least two sub-regions in isolation combine to cause the TCFNₜₒₜₐₗ to be approximately equal to the TCFN_{desired}.

In some embodiments, the Nth order comprises the first order (i.e., TCFN=TCF1), and TCFN_{desired} is approximately equal to 0 ppm/° C. Herein ‘approximately equal to 0 ppm/° C.’ does not necessarily involve reducing TCF1 to be exactly zero. Rather, it is sufficient to reduce TCF1 to be as close to zero as is practically possible. In some embodiments, this may involve reducing TCF1 to be less than 1 ppm/° C. In other embodiments, this may involve reducing TCF1 to be less than 0.1 ppm/° C. Still in other embodiments, this may involve reducing TCF1 to be less than 0.01 ppm/° C. In some embodiments, the Nth order comprises the second order (i.e., TCFN=TCF2), and TCFN_{desired} is approximately equal to 0 ppb/° C.². Herein ‘approximately equal to 0 ppb/° C.²’ does not necessarily involve reducing TCF2 to be exactly zero. Rather, it is sufficient to reduce TCF2 to be as close to zero as is practically possible. In some embodiments, this may involve reducing TCF2 to be less than 1 ppb/° C.². In other embodiments, this may involve reducing TCF2 to be less than 0.1 ppb/° C.². Still in other embodiments, this may involve reducing TCF2 to be less than 0.01 ppb/° C.².

In some embodiments, the Nth order comprises the first order (i.e., TCFN=TCF1), and TCFN_{desired} is equal to a nonzero value which, at least partly, compensates for the third order temperature coefficient of frequency of the composite eigenmode resonator element.

In some embodiments, each of the at least two sub-regions has the particular dopant type and the particular doping concentration.

In some embodiments, the geometry of the composite eigenmode resonator element further comprises one or more cavities in one or more of the at least two sub-regions.

In some embodiments, the effective mass of the composite eigenmode resonator element 104 and the sum of the effective masses of each of the at least two sub-regions in isolation have a difference of <10%.

In some embodiments, the composite eigenmode resonator device 100 is configured to operate as either (i) an oscillator or (ii) a resonating sensor.

In some embodiments, the composite eigenmode resonator device 100 comprises at least one of single crystal silicon, silicon carbide, polycrystalline silicon, quartz, graphene, and polycrystalline diamond.

### III. Examples of Passively Compensated Composite Eigenmode Resonators

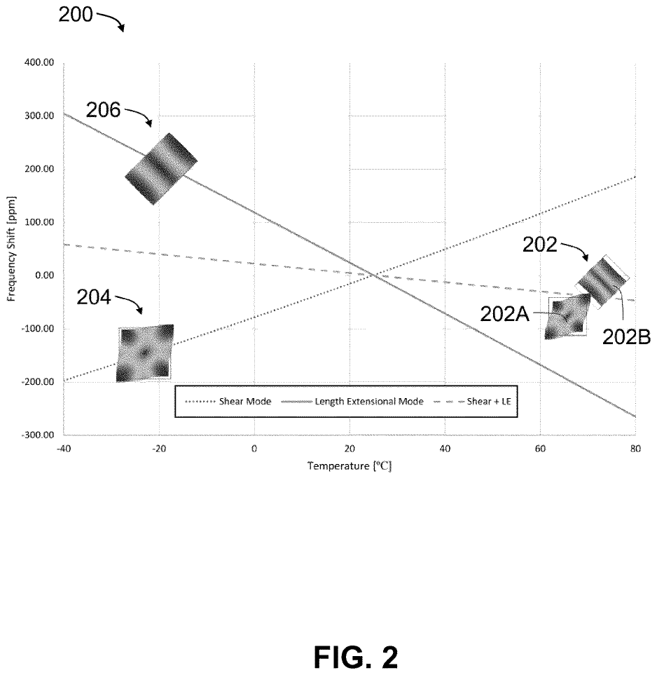

FIG. 2 contains a plot 200 depicting the frequency shift as a function of temperature of a composite eigenmode resonator element 202, which may be similar to or the same as the composite eigenmode resonator element 104 described above in connection with FIGS. 1A and 1B. Plot 200 compares the composite eigenmode resonator element 202, which includes a first sub-region 202A, resonating with a face-shear mode, and a second sub-region 202B, resonating with a length-extensional mode, to the constituent isolated eigenmodes (face-shear mode 204 and length-extensional mode 206). It can be seen in plot 200 that the frequency shift of the face-shear mode 204 in isolation increases significantly as the temperature increases, while the frequency shift of the length-extensional mode 206 in isolation decreases significantly as the temperature increases. The slope of the frequency shift as a function of temperature of the composite eigenmode resonator element 202 is significantly less than either of the constituent isolated eigenmodes. Thus, the temperature-induced frequency drift of the composite eigenmode resonator element 202 will be significantly reduced relative to a resonator element having only one of the constituent isolated eigenmodes.

It is important to note that the predictable response of TCFNₜₒₜₐₗ described by Equation 2 and depicted in plot 200 may hold true regardless of dopant type, doping concentration, or overall orientation with respect to the crystal axis of the composite eigenmode resonator element 104. While increasing the doping concentration or using a different dopant type may shift the TCFNₖ of the kth sub-region in isolation, TCFNₜₒₜₐₗ may still be possible to predict using Equation 2. Additionally, changing the overall orientation with respect to the crystal axis of the composite eigenmode resonator element 104 may shift the TCFNₖ of the kth sub-region in isolation, but TCFNₜₒₜₐₗ may still be possible to predict using Equation 2. Furthermore, the predictable response of TCF1ₜₒₜₐₗ (or TCFNₜₒₜₐₗ) is present in undoped silicon, but does not have a large impact on the temperature-induced frequency drift, as the majority of eigenmodes have a TCF1 of ~−30 ppm/° C. It is also important to note that there are limits to the linearity of Equation 2, which are discussed in detail in a following section.

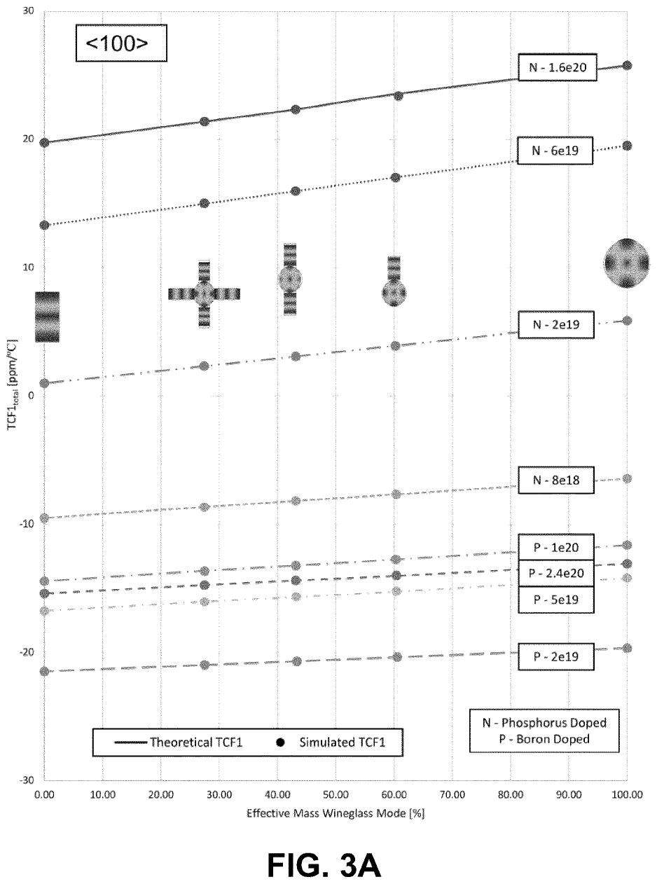

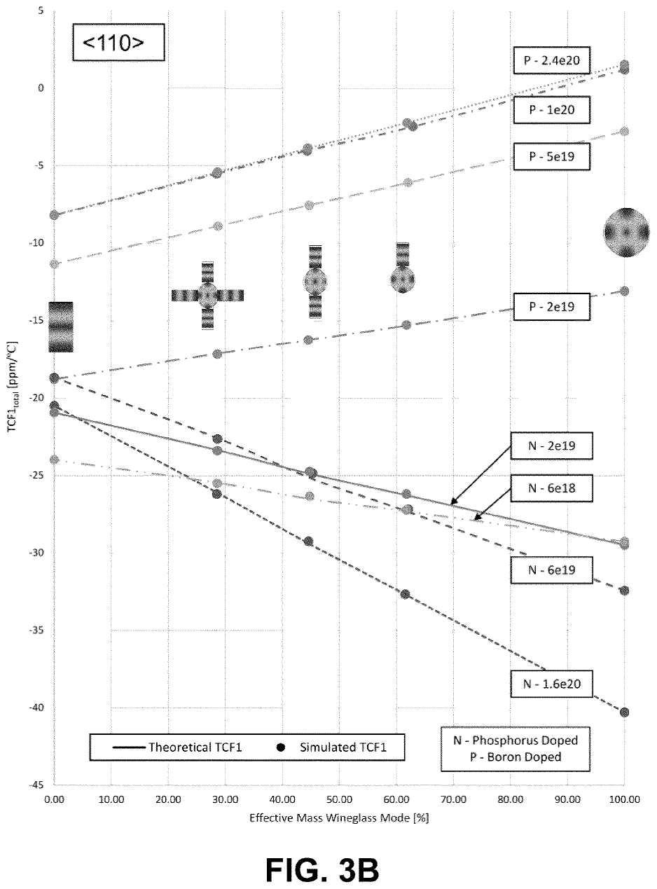

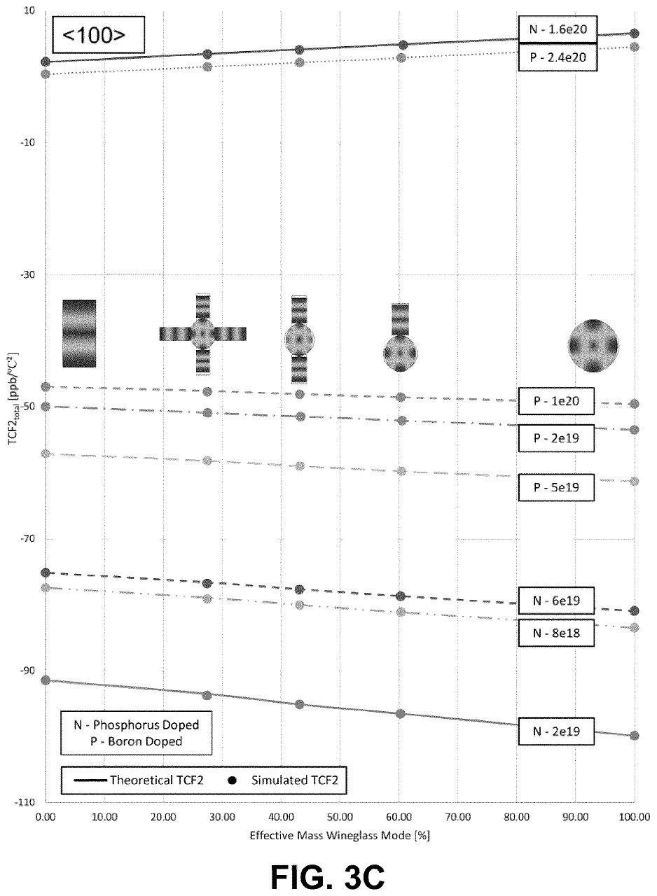

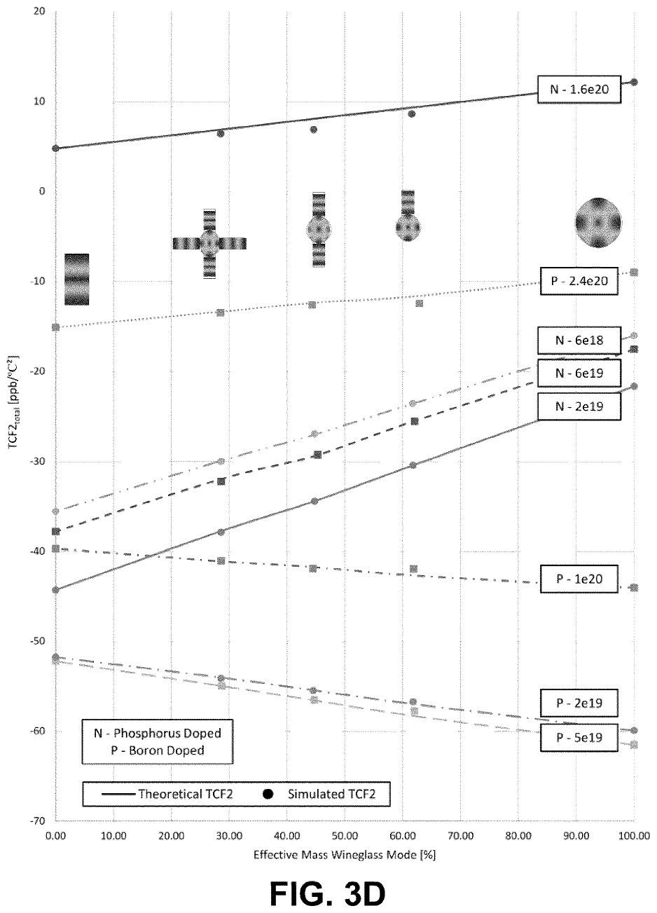

FIG. 3A depicts the predictable response of TCF1ₜₒₜₐₗ at different doping concentrations, with different dopant types, for a wineglass/length-extensional composite eigenmode in the <100> silicon lattice orientation.

FIG. 3B depicts the predictable response of TCF1ₜₒₜₐₗ at different doping concentrations, with different dopant types, for a wineglass/length-extensional composite eigenmode in the <110> silicon lattice orientation.

FIG. 3C depicts the predictable response of TCF2ₜₒₜₐₗ at different doping concentrations, with different dopant types, for a wineglass/length-extensional composite eigenmode in the <100> silicon lattice orientation.

FIG. 3D depicts the predictable response of TCF2ₜₒₜₐₗ at different doping concentrations, with different dopant types, for a wineglass/length-extensional composite eigenmode in the <110> silicon lattice orientation.

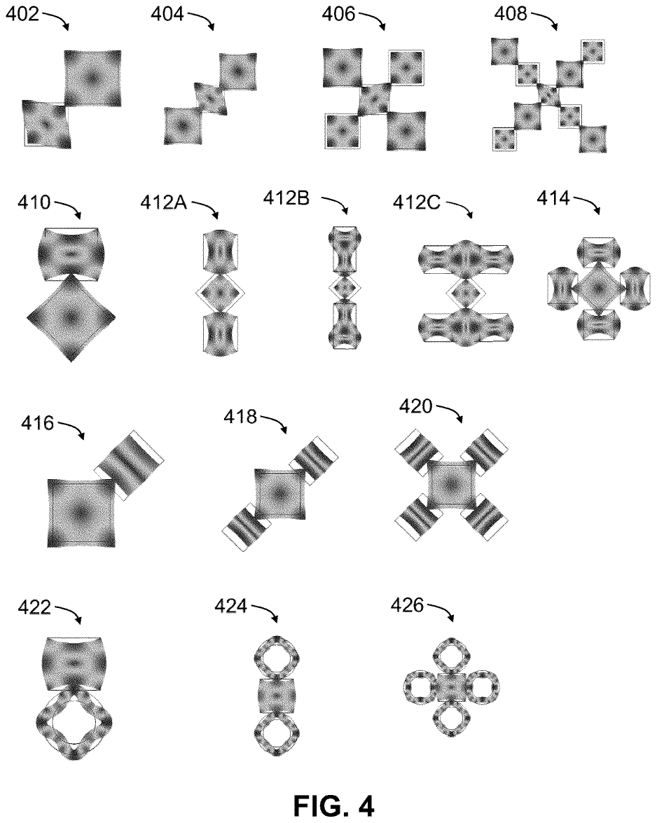

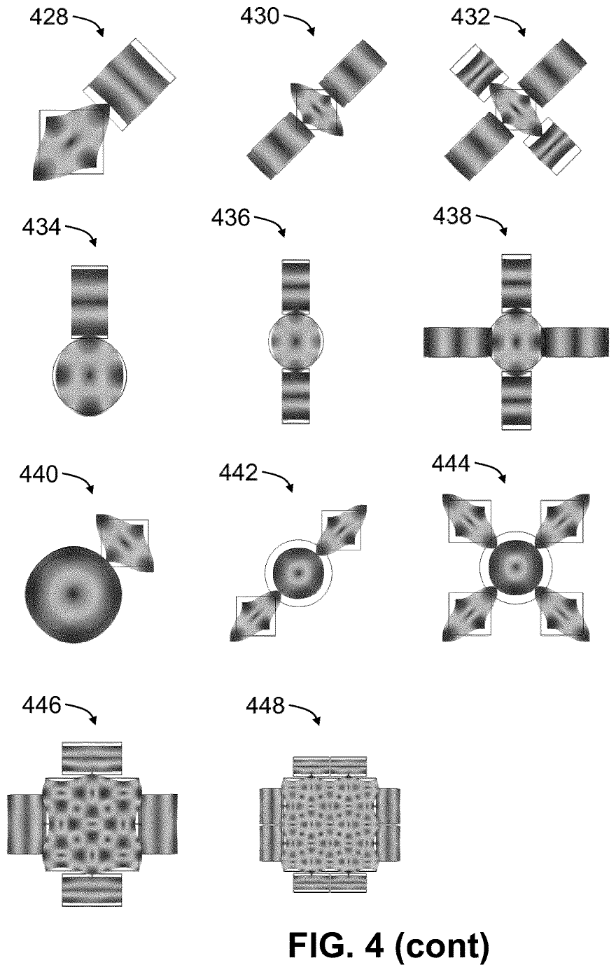

FIG. 4 depicts multiple examples of the composite eigenmode resonator element 104. Image 402 depicts a square-extensional/face-shear composite eigenmode resonator element with two sub-regions. Image 404 depicts a square-extensional/face-shear composite eigenmode resonator element with three sub-regions. Image 406 depicts a square-extensional/face-shear composite eigenmode resonator element with five sub-regions. Image 408 depicts a square-extensional/face-shear composite eigenmode resonator element with nine sub-regions. Image 410 depicts a square-extensional/Lamé composite eigenmode resonator element with two sub-regions. Image 412A depicts a square-extensional/Lamé composite eigenmode resonator element with three sub-regions, where two sub-regions are resonating with a Lamé eigenmode. Image 412B depicts a square-extensional/Lamé composite eigenmode resonator element with three sub-regions, where two sub-regions are resonating with a 1×2 higher order Lamé eigenmode. Image 412C depicts a square-extensional/Lamé composite eigenmode resonator element with three sub-regions, where two sub-regions are resonating with a 1×3 higher order Lamé eigenmode. Image 414 depicts a square-extensional/Lamé composite eigenmode resonator element with five sub-regions. Image 416 depicts a square-extensional/length-extensional composite eigenmode resonator element with two sub-regions. Image 418 depicts a square-extensional/length-extensional composite eigenmode resonator element with three sub-regions. Image 420 depicts a square-extensional/length-extensional composite eigenmode resonator element with five sub-regions. Image 422 depicts a 4th order annulus/Lamé composite eigenmode resonator element with two sub-regions. Image 424 depicts a 4th order annulus/Lamé composite eigenmode resonator element with three sub-regions. Image 426 depicts a 4th order annulus/Lamé composite eigenmode resonator element with five sub-regions. Image 428 depicts a face-shear/length-extensional composite eigenmode resonator element with two sub-regions. Image 430 depicts a face-shear/length-extensional composite eigenmode resonator element with three sub-regions. Image 432 depicts a face-shear/length-extensional composite eigenmode resonator element with five sub-regions. Image 434 depicts a wineglass/length-extensional composite eigenmode resonator element with two sub-regions. Image 436 depicts a wineglass/length-extensional composite eigenmode resonator element with three sub-regions. Image 438 depicts a wineglass/length-extensional composite eigenmode resonator element with five sub-regions. Image 440 depicts a face-shear/breathing mode composite eigenmode resonator element with two sub-regions. Image 442 depicts a face-shear/breathing mode composite eigenmode resonator element with three sub-regions. Image 444 depicts a face-shear/breathing mode composite eigenmode resonator element with five sub-regions. Image 446 depicts a width-extensional/Lamé composite eigenmode resonator element with five sub-regions, where the central sub-region is resonating with a 3^{rd} order Lamé eigenmode. Image 448 depicts a width-extensional/Lamé composite eigenmode resonator element with nine sub-regions, where the central sub-region is resonating with a 5th order Lamé eigenmode. A skilled reader will note that the sub-regions of the width-extensional/Lamé composite eigenmode resonator element depicted in image 446 and image 448 include a connection region defined by a bar.

### IV. Methods of Passively Compensating Composite Eigenmode Resonators

Designing the composite eigenmode resonator element 104 to achieve a precise temperature-induced frequency response requires at least two sub-regions, wherein each of the at least two sub-regions in isolation resonate with an eigenmode from a set of at least two eigenmodes and have a TCFNₖ. While it is possible that, in different example embodiments, various different numbers of sub-regions resonating with various eigenmodes may be utilized, for purposes of clarity, many of the examples described herein demonstrate methods of passively compensating composite eigenmode resonator elements with five or fewer sub-regions.

Initially, the composite eigenmode resonator element 104 may be coarsely designed to have a TCFNₜₒₜₐₗ approximately equal to a desired Nth order temperature coefficient of frequency (TCFN_{desired}) by choosing sub-regions resonating with eigenmodes with TCFNₖs that are above and below a desired value (for example, TCF1_{desired}=0 ppm/° C. or TCF2_{desired}=0 ppb/° C.²). However, there are a limited number of common eigenmodes to select from (e.g., Lamé, face-shear, square-extensional, width-extensional, length-extensional, Nth order annulus, breathing, wineglass, or higher order Lamé eigenmodes), and it may not always be possible to select two eigenmodes with the same absolute value of TCFNₖ but with opposite signs. Thus, simply combining two eigenmodes will not generally cause TCFNₜₒₜₐₗ=TCFN_{desired}. Further tuning will be required in most cases.

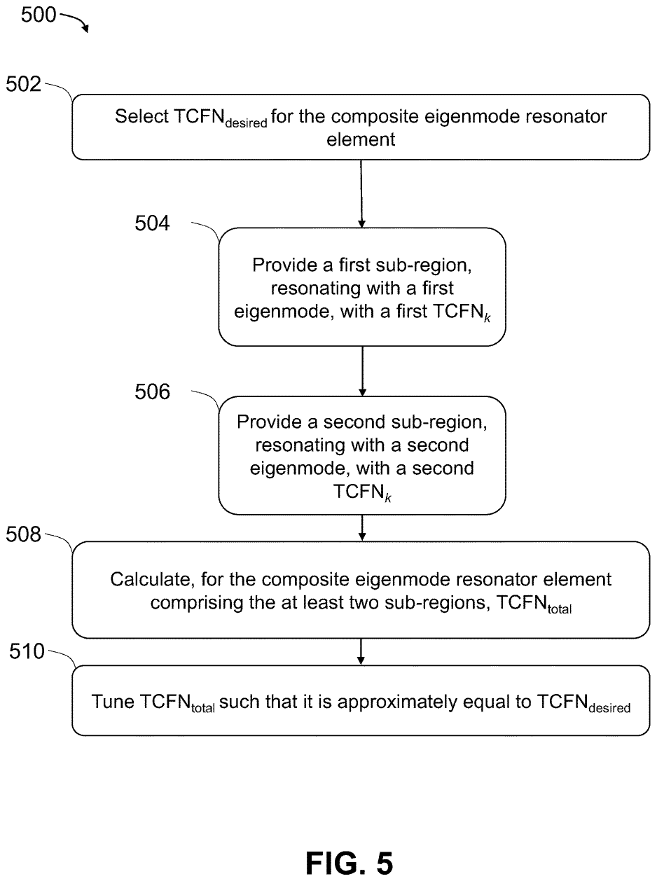

FIG. 5 depicts a flowchart 500 of a method to tune the Nth order temperature-induced frequency response of the composite eigenmode resonator device 100. At step 502 the method involves selecting TCFN_{desired} for the composite eigenmode resonator element 104. In line with the discussion above, the composite eigenmode resonator element 104 comprises at least two sub-regions, wherein each of the at least two sub-regions in isolation resonate with an eigenmode from a set of at least two eigenmodes and have a TCFNₖ.

At step 504, the method involves providing a first sub-region of the composite eigenmode resonator element 104. The first sub-region in isolation resonates with a first eigenmode from the set of at least two eigenmodes and has a particular dopant type, a particular doping concentration, a first orientation with respect to the crystal axis, and a first TCFNₖ. And at step 506 the method involves providing a second sub-region of the composite eigenmode resonator element 104. The second sub-region in isolation resonates with a second eigenmode from the set of at least two eigenmodes and has the particular dopant type, the particular doping concentration, a second orientation with respect to the crystal axis, and a second TCFNₖ.

At step 508 the method involves determining TCFNₜₒₜₐₗ of the composite eigenmode resonator element 104 comprising the at least two sub-regions, which can be accomplished using Equation 2 above (or with a computer program if desired).

At step 510 the method involves tuning TCFNₜₒₜₐₗ such that it is approximately equal to TCFN_{desired}. Tuning TCFNₜₒₜₐₗ includes altering at least one of the first or second TCFNₖ such that either (i) the first TCFNₖ is greater than TCFN_{desired} and the second TCFNₖ is less than TCFN_{desired} or (ii) the first TCFNₖ is less than TCFN_{desired} and the second TCFNₖ is greater than TCFN_{desired}.

In some embodiments, tuning TCFNₜₒₜₐₗ such that it is approximately equal to TCFN_{desired} may be done by one or a combination of (i) performing effective mass tuning, (ii) performing resonance frequency tuning, or (iii) adding cavities to one or more of the at least two sub-regions, such that at least one of the first or second TCFNₖ is altered. Furthermore, if done in combination, effective mass tuning, resonance frequency tuning, and adding cavities to one or more of the at least two sub-regions may be applied in any sequence. The method depicted in flowchart 500 may be performed using a parametric sweep approach, using methods now known and later developed, to iteratively design the composite eigenmode resonator element 104.

Herein, effective mass tuning means to modify the effective mass percentage of a particular eigenmode from the set of at least two eigenmodes on the composite eigenmode resonator element 104, without altering the resonance frequency of the particular eigenmode. Effective mass tuning may be done by one or a combination of (i) adding or removing sub-regions resonating with the particular eigenmode or (ii) modifying the size of a sub-region resonating with the particular eigenmode, without altering the resonance frequency of the particular eigenmode.

Adding or removing sub-regions will necessarily alter the number of n sub-regions in Equation 2. Thus, by adding or removing sub-regions, the weighted average TCFNₜₒₜₐₗ can be tuned to be approximately equal to TCFN_{desired}.

Modifying the size of a sub-region resonating with the particular eigenmode without altering the resonance frequency of the particular eigenmode may be accomplished by utilizing specific types of eigenmodes. For example, altering the width of a sub-region resonating with a length-extensional eigenmode or changing the height of a sub-region resonating with an in-plane eigenmode (e.g., Lamé, face-shear, etc.) will modify the size (and thus effective mass) of the sub-region. Some eigenmodes can also be distributed along specific axes, such as the Lamé eigenmode in the x and y planar directions and the length-extensional eigenmode in the length-wise direction. Doubling a dimension of a sub-region that exhibits a distributable mode will result in that sub-region exhibiting the corresponding 2^{nd} order eigenmode without altering the resonance frequency.

In some cases, effective mass tuning may be more advantageous than other methods when tuning TCFNₜₒₜₐₗ such that it is approximately equal to TCFN_{desired}. For instance, it is possible to implement effective mass tuning while maintaining the maximum displacement amplitude across the set of at least two eigenmodes, which can make fabricated MEMS resonator devices more practical to operate in the real world because displacement amplitude improves signal to noise ratio.

As described herein, resonance frequency tuning means to scale the dimensions of a particular sub-region resonating with a particular eigenmode in such a manner that only the resonance frequency of the particular eigenmode changes, but not the mode shape (e.g., making a square sub-region exhibiting a square-extensional mode larger or smaller, but not rectangular). Altering the resonance frequency of the particular eigenmode will result in a resonance frequency difference between the altered eigenmode and the other eigenmodes. This will weaken the mechanical coupling of the altered eigenmode and the other eigenmodes in the overall composite eigenmode. The weak coupling will cause one of the eigenmodes to dominate the others in terms of displacement amplitude at the new resonance frequency. This will effectively increase the effective mass of the dominant eigenmode with respect to the other eigenmodes and shift the TCFNₜₒₜₐₗ of the resonator toward the TCFNₖ of the dominant eigenmode.

Tuning TCFNₜₒₜₐₗ such that it is approximately equal to TCFN_{desired} may also be accomplished by adding cavities to a particular sub-region resonating with a particular eigenmode. Adding cavities to one or more of the sub-regions will slightly “distort” the composite eigenmode. As used herein, “distort” means to introduce stray vibrations, thereby causing a deviation from the composite eigenmode present in the equivalent resonator element without cavities. Adding cavities to one or more of the at least two sub-regions will distort the composite eigenmode by changing the contribution of the elastic constants of silicon (c₁₁, c₁₂, and c₄₄) to the composite eigenmode, thereby shifting the TCFNₜₒₜₐₗ of the composite eigenmode.

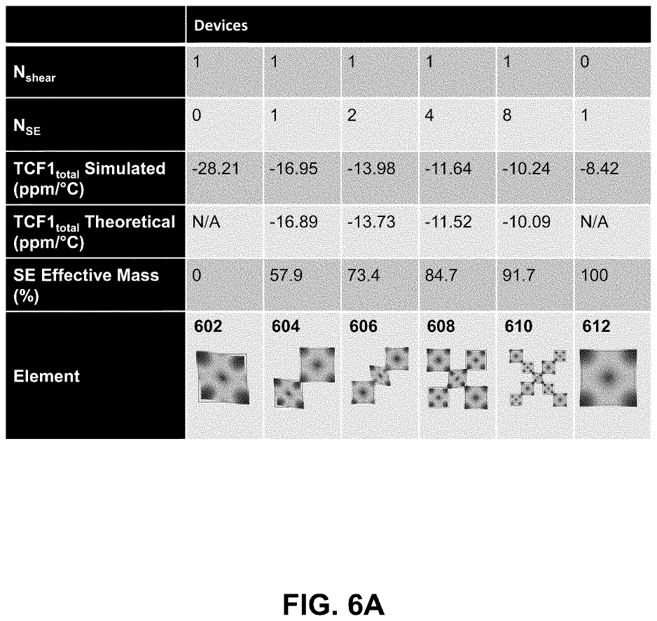

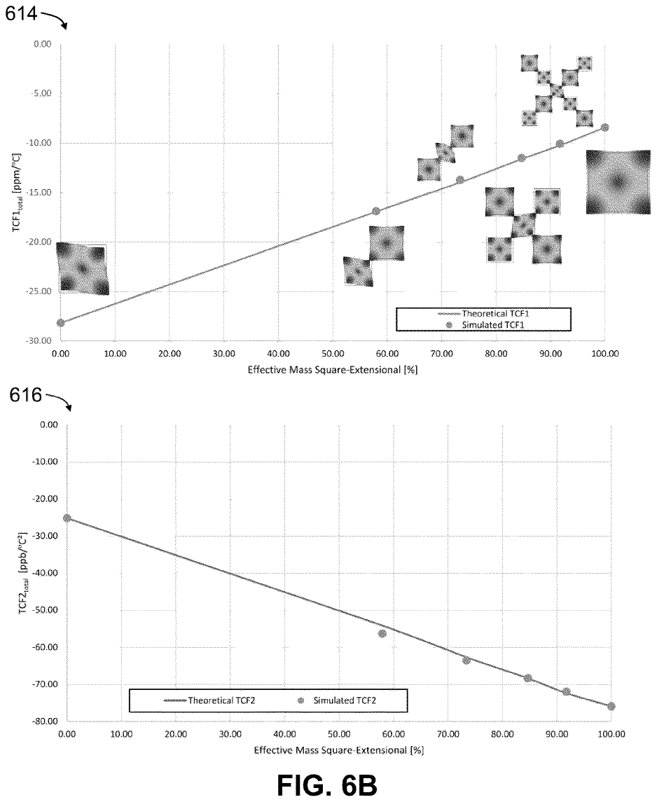

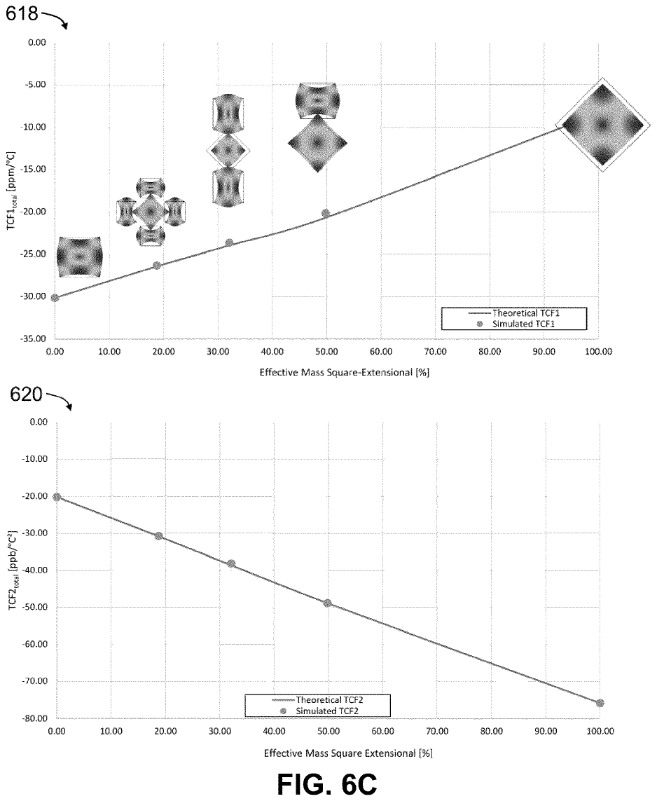

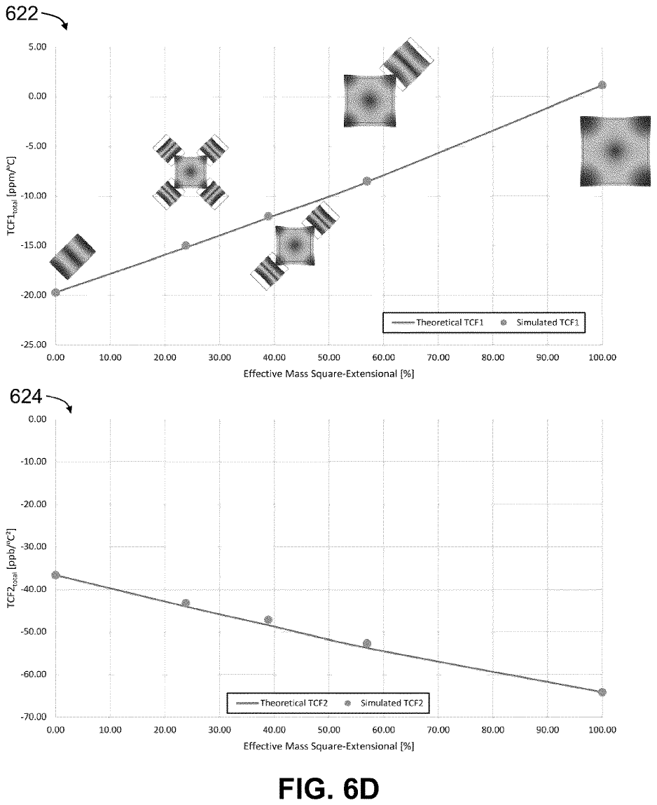

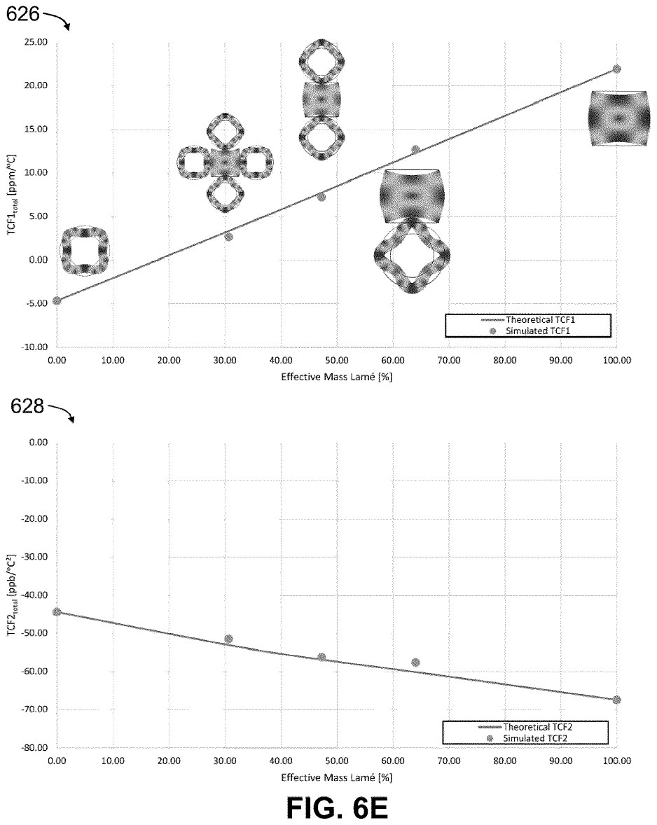

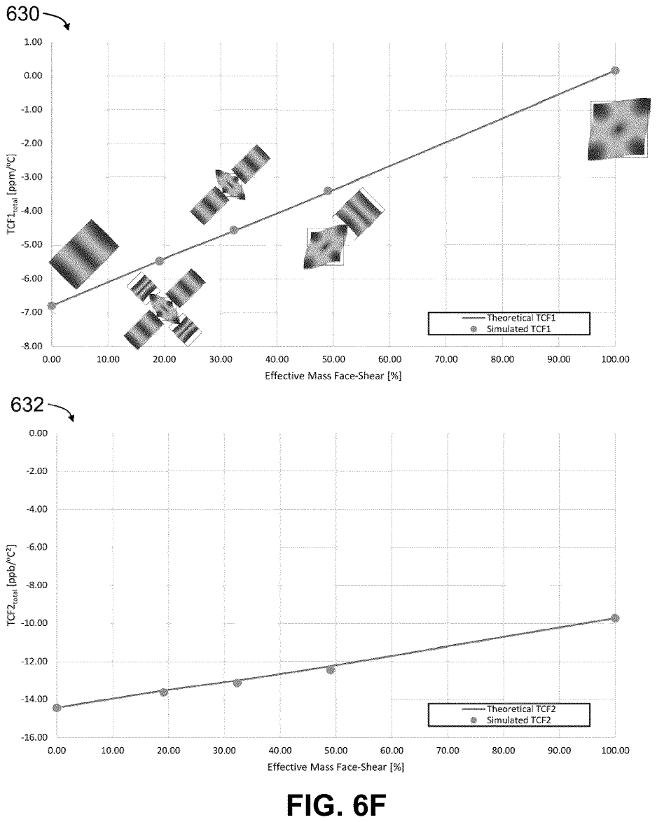

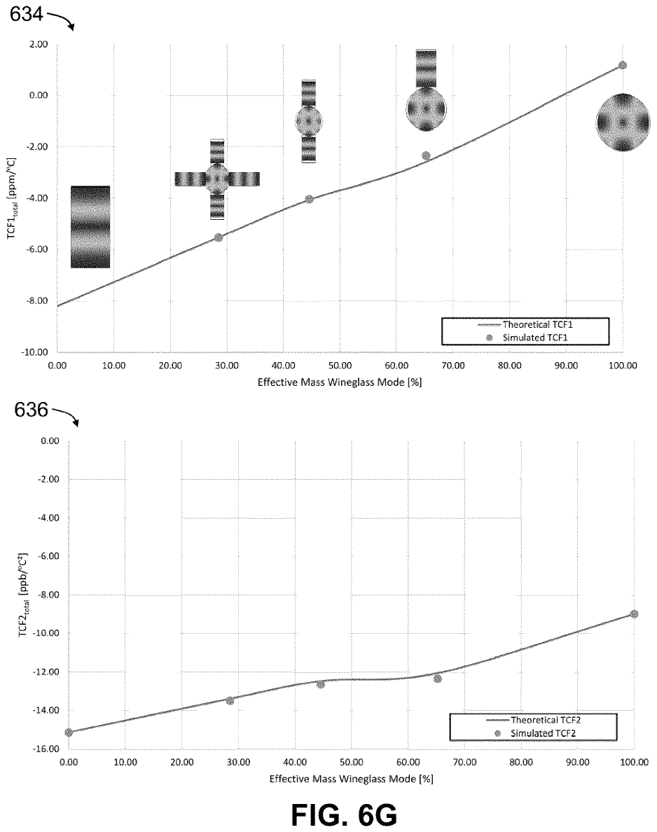

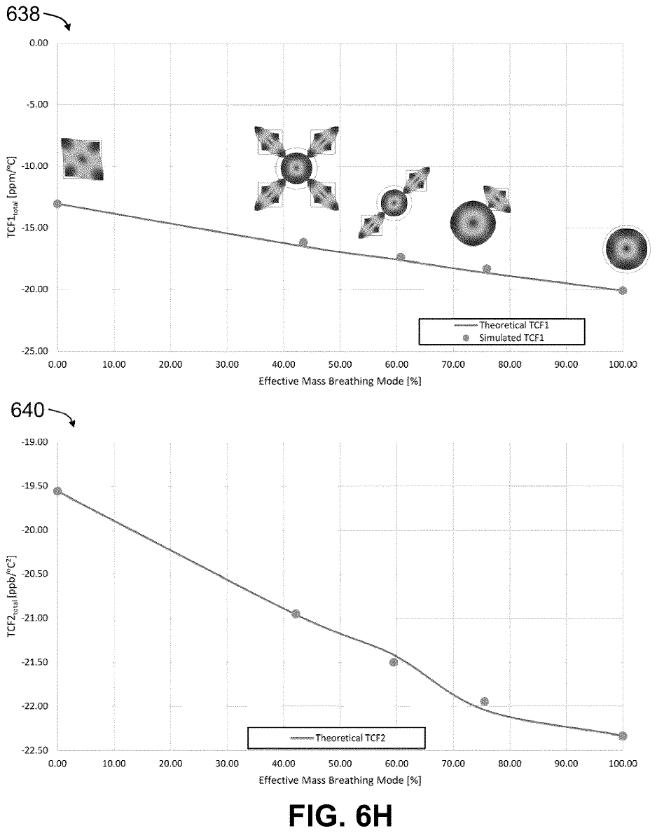

FIG. 6A depicts example results of effective mass tuning via adding or removing sub-regions resonating with the particular eigenmode. In this example, TCF1ₜₒₜₐₗ of a face-shear/square-extensional composite eigenmode is tuned. In this example, the resonator elements are orientated to the <100> silicon lattice orientation and N-doped to a concentration of 2.00×10¹⁹ atoms/cm³. The depicted values of the square-extensional (SE) effective mass are determined according to the equation: SE effective mass=meff_{SE}/meffₜₒₜₐₗ. Resonator element 602 has a single sub-region resonating in an isolated face-shear eigenmode, such that the element 602 includes no square-extensional eigenmodes and the SE effective mass=0%. When the SE effective mass=0%, the resultant isolated face-shear eigenmode has a TCF1ₜₒₜₐₗ=−28.21 ppm/° C. As shown by resonator elements 604, 606, 608, and 610, one or more square-extension sub-regions may be placed at one or more corners of a face-shear sub-region to push the TCF1ₜₒₜₐₗ of the composite eigenmode resonator element 104 towards the TCF1ₜₒₜₐₗ of an isolated square-extensional eigenmode (which is represented by resonator element 612). As the number of SE sub-regions increases, TCF1ₜₒₜₐₗ increases and approaches the case where SE effective mass=100% (i.e., resonator element 612) and the resultant isolated square-extensional eigenmode has a TCF1ₜₒₜₐₗ=−8.42 ppm/° C.

FIG. 6B contains plot 614 which plots the example results of the effective mass tuning of TCF1ₜₒₜₐₗ for a face-shear/square-extensional composite eigenmode shown in FIG. 6A. In plot 614, the face-shear/square-extensional composite eigenmode resonator element includes a single face-shear mode sub-region placed at a point of maximum displacement of the square-extensional sub-region. In this example, the composite eigenmode resonator element is orientated to the <100> silicon lattice orientation and N-doped to a concentration of 2.00×10¹⁹ atoms/cm³. The SE effective mass=meff_{SE}/meffₜₒₜₐₗ. As shown in plot 614, the SE effective mass is varied by adjusting the number of square-extensional sub-regions. As further shown in FIG. 6B, plot 616 depicts the effects on TCF2ₜₒₜₐₗ that result from changing the SE effective mass of the composite eigenmode resonator element by adjusting the number of square-extensional sub-regions, in the same or similar manner as in connection with plot 614.

FIG. 6C contains plot 618 which depicts an example of effective mass tuning of TCF1ₜₒₜₐₗ for a square-extensional/Lamé composite eigenmode. In plot 618, the square-extensional/Lamé composite eigenmode resonator element includes a single square-extensional mode sub-region placed at a point of maximum displacement of the Lamé sub-region. In this example, the composite eigenmode resonator element is orientated in the <110> silicon lattice orientation and N-doped to a concentration of 2.00×10¹⁹ atoms/cm³. The SE effective mass=meff_{SE}/meffₜₒₜₐₗ. As shown in plot 618, the SE effective mass is varied by adjusting the number of Lamé sub-regions. As further shown in FIG. 6C, plot 620 depicts the effects on TCF2ₜₒₜₐₗ that result from changing the SE effective mass of the composite eigenmode resonator element by adjusting the number of Lamé sub-regions, in the same or similar manner as in connection with plot 618.

FIG. 6D contains plot 622 which depicts an example of effective mass tuning of TCF1ₜₒₜₐₗ for square-extensional/length-extensional composite eigenmode. In plot 622, the square-extensional/length-extensional composite eigenmode resonator element includes a single square-extensional mode sub-region placed at a point of maximum displacement of the length-extensional sub-region. In this example, the composite eigenmode resonator element is orientated in the <100> silicon lattice orientation and N-doped to a concentration of 6.00×10¹⁹ atoms/cm³. The SE effective mass=meff_{SE}/meffₜₒₜₐₗ. As shown in plot 622, the SE effective mass of the composite resonator element is varied by adjusting the number of length-extensional mode sub-regions. As further shown in FIG. 6D, plot 624 depicts of the effects on TCF2ₜₒₜₐₗ that result from changing the SE effective mass of the composite eigenmode resonator element by adjusting the number of length-extensional sub-regions, in the same or similar manner as in connection with plot 622.

FIG. 6E contains plot 626 which depicts an example of effective mass tuning of TCF1ₜₒₜₐₗ for a Lamé/Nth order annulus composite eigenmode. In plot 626, the Lamé/Nth order annulus composite eigenmode resonator element includes a single Lamé mode sub-region placed at a point of maximum displacement of the Nth order annulus. The Lamé sub-region is orientated in the <100> silicon lattice orientation and N-doped to a concentration of 7.5×10¹⁹ atoms/cm³. The Lamé effective mass=meff_{Lamé}/meffₜₒₜₐₗ. As shown in plot 626, the Lamé effective mass of the composite resonator element is varied by adjusting the number of Nth order annulus mode sub-regions. As further shown in FIG. 6E, plot 628 depicts the effects on TCF2ₜₒₜₐₗ that result from changing the Lamé effective mass of the composite eigenmode resonator element by adjusting the number of Nth order annulus sub-regions, in the same or similar manner as in connection with plot 626.

FIG. 6F contains plot 630 which depicts an example of effective mass tuning of TCF1ₜₒₜₐₗ for a face-shear/length-extensional composite eigenmode. In plot 630, the face-shear/length-extensional composite eigenmode resonator element includes a single face-shear sub-region placed at a point of maximum displacement of the length-extensional subregion. In this example, the composite eigenmode resonator element is orientated in the <100> silicon lattice orientation and P-doped to a concentration of 2.4×10²⁰ atoms/cm³. The face-shear (FS) effective mass=meff_{FS}/meffₜₒₜₐₗ. As shown in plot 630, the FS effective mass of the composite resonator element is varied by adjusting the number of length-extensional mode sub-regions. As further shown in FIG. 6F, plot 632 depicts the effects on TCF2ₜₒₜₐₗ that result from changing the FS effective mass of the composite eigenmode resonator element by adjusting the number of length-extensional sub-regions, in the same or similar manner as in connection with plot 630.

FIG. 6G contains plot 634 which depicts an example of effective mass tuning of TCF1ₜₒₜₐₗ for a wineglass/length-extensional composite eigenmode. In plot 634, the wineglass/length-extensional composite eigenmode resonator element includes a single wineglass sub-region placed at a point of maximum displacement of the length-extensional sub-region. In this example, the composite eigenmode resonator element is orientated in the <110> silicon lattice orientation and P-doped to a concentration of 2.4×10²⁰ atoms/cm³. The wineglass effective mass=meff_{wineglass}/meffₜₒₜₐₗ. As shown in plot 634, the wineglass effective mass of the composite resonator element is varied by adjusting the number of length-extensional mode sub-regions. As further shown in FIG. 6G, plot 636 depicts the effects on TCF2ₜₒₜₐₗ that result from changing the wineglass effective mass of the composite eigenmode resonator element by adjusting the number of length-extensional sub-regions, in the same or similar manner as in connection with plot 634.

FIG. 6H contains plot 638 which depicts an example of effective mass tuning of TCF1ₜₒₜₐₗ a breathing/face-shear composite eigenmode. In plot 638, the breathing/face-shear composite eigenmode resonator element includes a single breathing mode sub-region placed at a point of maximum displacement of the face-shear sub-region. In this example, the composite eigenmode resonator element is orientated in the <110> silicon lattice orientation and P-doped to a concentration of 2.4×10²⁰ atoms/cm³. The breathing mode effective mass=meff_{breathing}/meffₜₒₜₐₗ. As shown in plot 638, the breathing mode effective mass of the composite resonator element is varied by adjusting the number of face-shear sub-regions. As further shown in FIG. 6H, plot 640 depicts the effects on TCF2ₜₒₜₐₗ that result from changing the breathing effective mass of the composite eigenmode resonator element by adjusting the number of face-shear sub-regions, in the same or similar manner as in connection with plot 638.

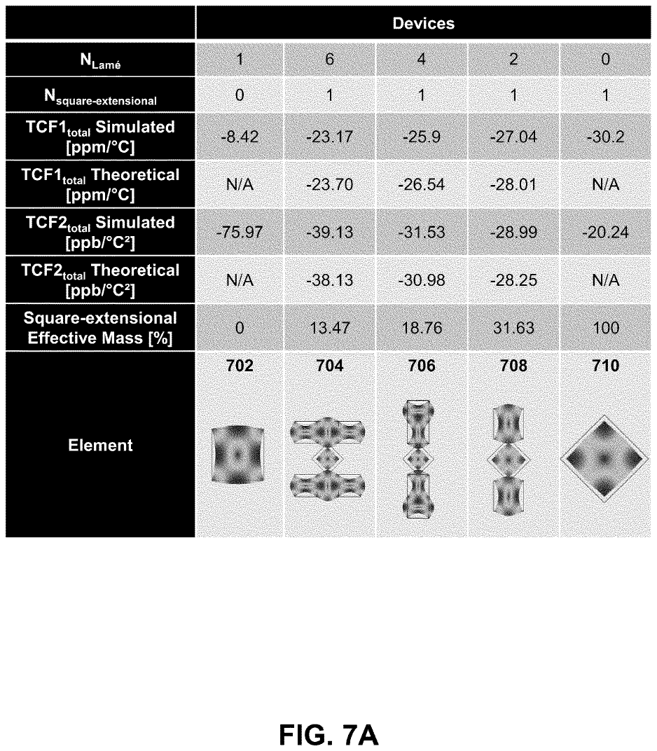

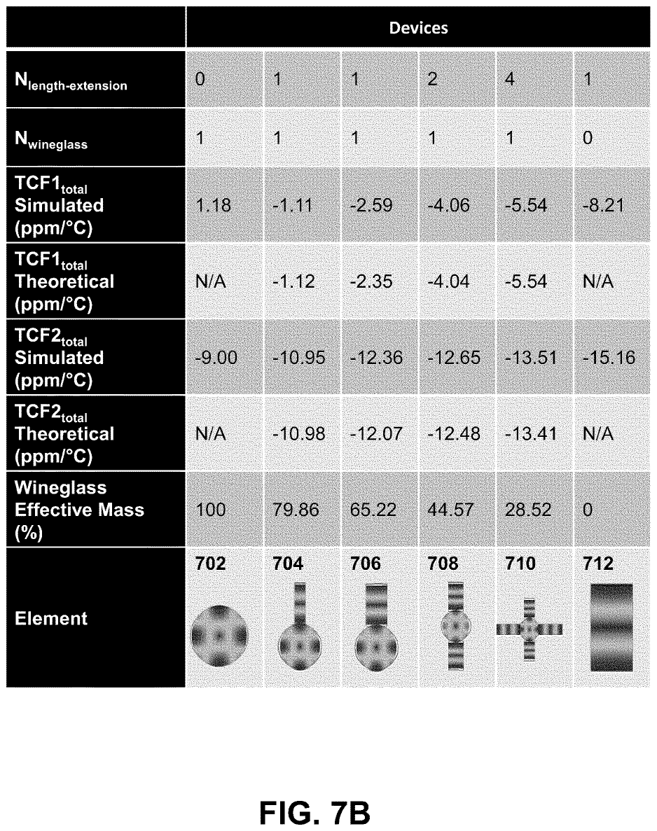

FIG. 7A depicts example results of effective mass tuning via modifying the size of a sub-region resonating with the particular eigenmode, without altering the resonance frequency of the particular eigenmode. In this example, the TCF1ₜₒₜₐₗ and TCF2ₜₒₜₐₗ for a Lamé/square-extensional composite eigenmode is tuned. In this example, the composite eigenmode resonator elements are orientated to the <110> silicon lattice orientation and N-doped to a concentration of 2.00×10¹⁹ atoms/cm³. Again, the depicted values of the square-extensional (SE) effective mass are determined according to the equation: SE effective mass=meff_{SE}/meffₜₒₜₐₗ. Here, element 708 depicts a square-extensional/Lamé composite eigenmode resonator element with three sub-regions, in which a first sub-region is resonating with a square-extensional eigenmode and two sub-regions extending from opposite corners of the first sub-region are resonating with a Lamé eigenmode. Element 708 has a simulated TCF1ₜₒₜₐₗ=−27.04 ppm/° C. and a simulated TCF2ₜₒₜₐₗ=−28.99 ppb/° C.². Moving to element 706, it can be seen that a side length of the two sub-regions resonating with a Lamé eigenmode has been doubled. Thus, the two sub-regions exhibit a higher order Lamé eigenmode, which resonates with the same resonance frequency but with additional effective mass, which will shift the TCFNₜₒₜₐₗ of element 706 towards that of the pure Lamé eigenmode (element 702). Similarly, element 704 has further increased the side length of the two sub-regions resonating with a Lamé eigenmode, further shifting the temperature coefficients of frequency to a simulated TCF1ₜₒₜₐₗ=−23.17 ppm/° C. and a simulated TCF2ₜₒₜₐₗ=−39.13 ppb/° C.².

FIG. 7B depicts example results of effective mass tuning a wineglass/length-extensional composite eigenmode by both (i) adding or removing sub-regions resonating with the particular eigenmode and (ii) modifying the size of a sub-region resonating with the particular eigenmode, without altering the resonance frequency of the particular eigenmode. In this example, the composite eigenmode resonator elements are orientated to the <110> silicon lattice orientation and P-doped to a concentration of 2.4×10²⁰ atoms/cm³. The depicted values of the wineglass effective mass are determined according to the equation: wineglass effective mass=meff_{wineglass}/meffₜₒₜₐₗ. Resonator element 702 has a single sub-region resonating in an isolated wineglass eigenmode, such that the wineglass effective mass=100%. When the wineglass effective mass=100%, the resultant isolated wineglass eigenmode has a TCF1ₜₒₜₐₗ=1.18 ppm/° C. As shown by resonator elements 704, 706, 708, and 710, one or more length-extension (LE) sub-regions may be placed at points of maximum displacement of the wineglass sub-region to push the TCF1ₜₒₜₐₗ towards the TCF1ₜₒₜₐₗ of an isolated length-extensional eigenmode (which is represented by resonator element 712). As the number of LE sub-regions increase, TCF1ₜₒₜₐₗ increases until the wineglass effective mass=0% and the resultant isolated length-extensional eigenmode has a TCF1ₜₒₜₐₗ=−8.21 ppm/° C. Additionally, comparing element 704 to element 706, it can be seen that modifying the size of the sub-region resonating with the length-extensional eigenmode, without altering the resonance frequency, can tune TCFNₜₒₜₐₗ. Element 704 has TCF1ₜₒₜₐₗ=−1.11 ppm/° C., but by increasing the width of the sub-region resonating with the length-extensional eigenmode, element 706 has TCF1ₜₒₜₐₗ=−2.59 ppm/° C.

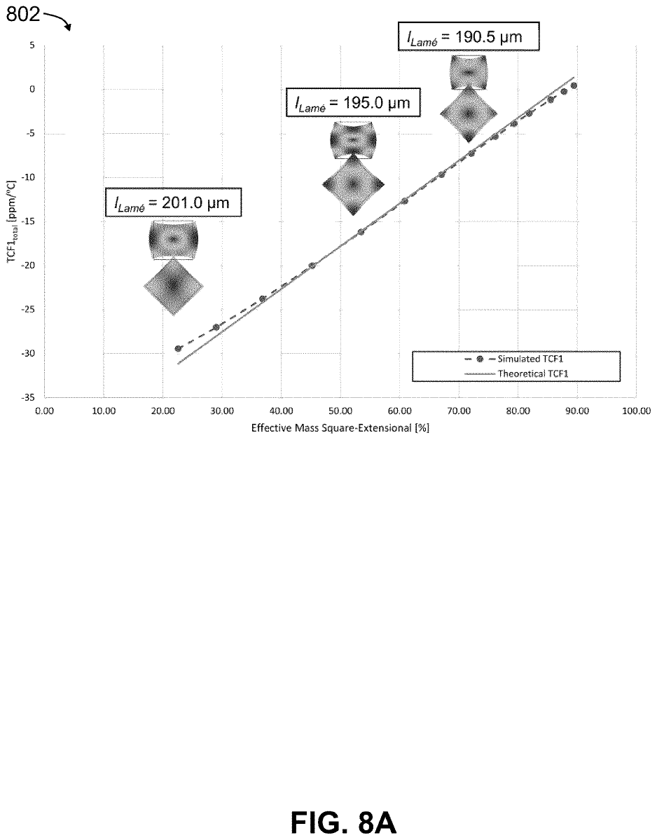

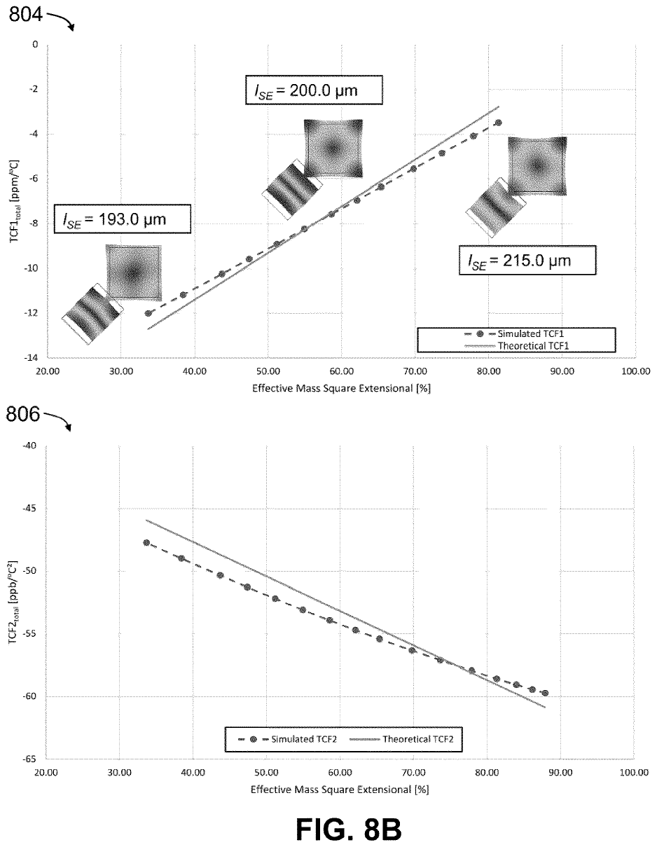

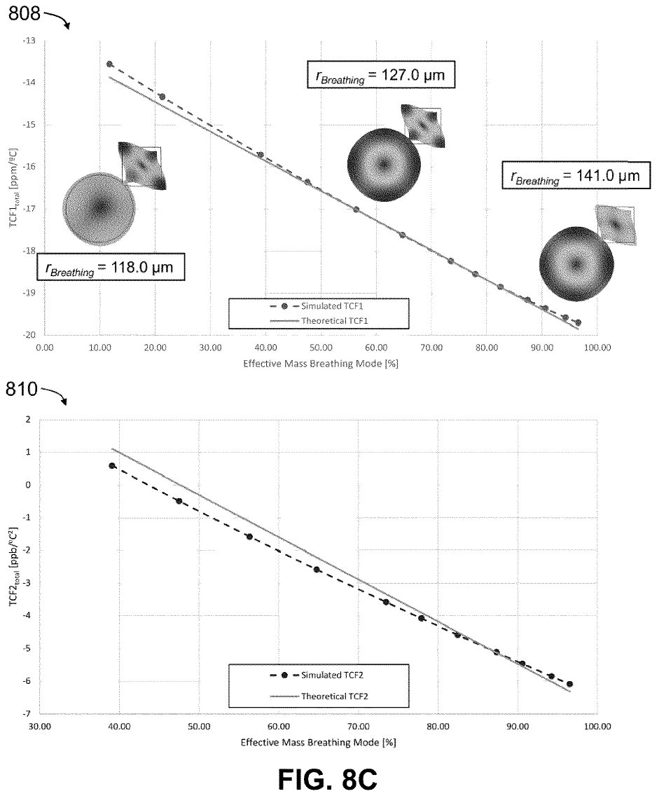

FIGS. 8A-C depict the effect of resonance frequency tuning TCF1ₜₒₜₐₗ and TCF2ₜₒₜₐₗ. FIG. 8A contains plot 802 which depicts an example of resonance frequency tuning via scaling the dimensions of a square-extensional/Lamé composite eigenmode to tune TCF1ₜₒₜₐₗ. In plot 802, the square-extensional/Lamé composite eigenmode resonator element includes a single SE mode sub-region and a single Lamé mode sub-region extending from a corner of the SE mode sub-region, each of which is orientated to the <110> silicon lattice orientation and N-doped to a concentration of 1.7×10²⁰ atoms/cm³. Again, the SE effective mass=meff_{SE}/meffₜₒₜₐₗ. As shown in plot 802, the SE effective mass of the composite resonator element is varied by adjusting the side length of the Lamé mode sub-region, I_{Lamé}, particular values of which are indicated in FIG. 8A.

FIG. 8B contains plot 804 which depicts an example of resonance frequency tuning via scaling the dimensions of a square-extensional/length-extensional (SE/LE) composite eigenmode to tune TCF1ₜₒₜₐₗ. In plot 804, the SE/LE composite eigenmode resonator element includes a single SE mode sub-region and a single LE mode sub-region extending from a corner of the SE mode sub-region, each of which is orientated to the <100> silicon lattice orientation and N-doped to a concentration of 6.0×10¹⁹ atoms/cm³. Again, the SE effective mass=meff_{SE}/meffₜₒₜₐₗ. As shown in plot 804, the SE effective mass of the composite resonator element is varied by adjusting the side length of the SE mode sub-region, l_{SE}, particular values of which are indicated in FIG. 8B. As further shown in FIG. 8B, plot 806 depicts the effects on TCF2ₜₒₜₐₗ that result from changing the SE effective mass of the composite resonator element by adjusting the side length of the SE mode sub-region, l_{SE}, in the same or similar manner as in connection with plot 804.

FIG. 8C contains plot 808 which depicts an example of resonance frequency tuning via scaling the dimensions of a breathing/face-shear composite eigenmode to tune TCF1ₜₒₜₐₗ. In plot 808, the breathing/face-shear composite eigenmode resonator element includes a single breathing mode sub-region and a single face-shear mode sub-region placed at a point of maximum displacement of the breathing mode sub-region, each of which is orientated to the <110> silicon lattice orientation and P-doped to a concentration of 2.4×10²⁰ atoms/cm³. The breathing mode effective mass=meff_{breathing}/meffₜₒₜₐₗ. As shown in plot 808, the breathing mode effective mass of the composite resonator element is varied by adjusting the radius of the breathing mode sub-region, r_{breathing}, particular values of which are indicated in FIG. 8C. As further shown in FIG. 8C, plot 810 depicts the effects on TCF2ₜₒₜₐₗ that result from changing the breathing mode effective mass of the composite resonator element by adjusting the radius of the breathing mode sub-region, r_{breathing}, in the same or similar manner as in connection with plot 808.

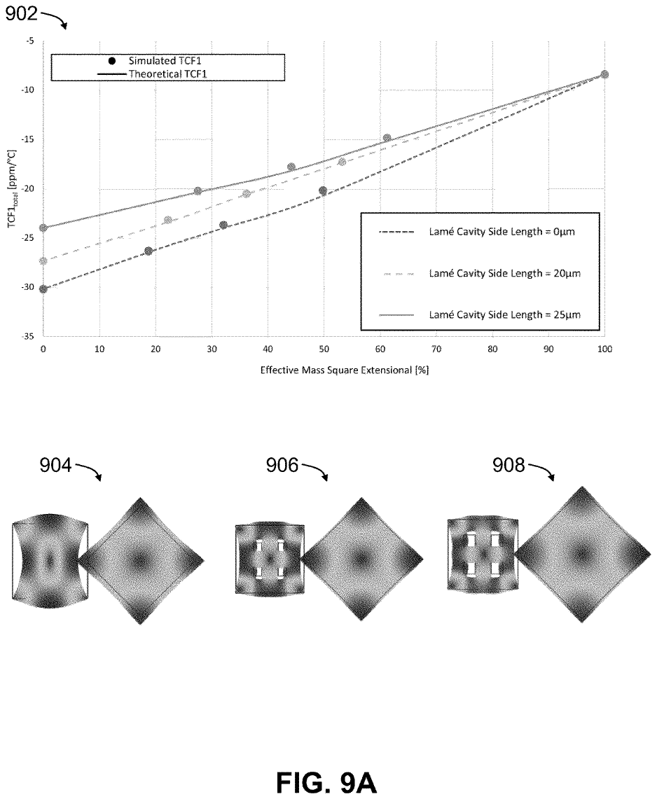

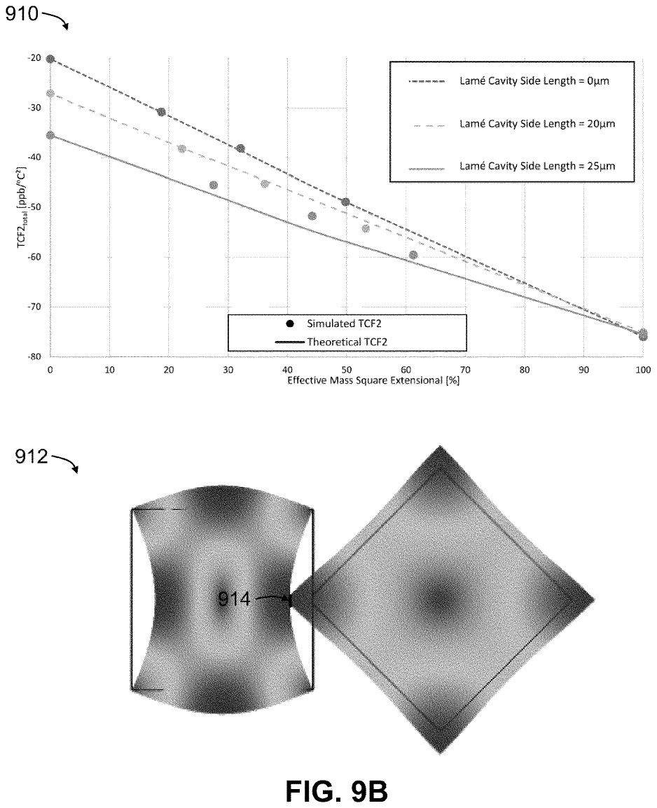

FIG. 9A depicts the effect of tuning TCF1ₜₒₜₐₗ via adding cavities to one or more of the at least two sub-regions. In the depicted example, the composite eigenmode is a square-extensional (SE)/Lamé composite eigenmode. Plot 902 depicts an example resultant effect of adding cavities to the SE/Lamé composite eigenmode in order to tune TCF1ₜₒₜₐₗ. Image 904 depicts the SE/Lamé composite eigenmode without cavities (which corresponds to the dotted line in plot 902). Image 906 depicts the SE/Lamé composite eigenmode with cavities with a side length of 20 μm (which corresponds to the dashed line in plot 902). Image 908 depicts the SE/Lamé composite eigenmode with cavities with a side length of 25 μm (which corresponds to the solid line in plot 902). As shown in plot 902, adding cavities to the SE/Lamé composite eigenmode can increase the sensitivity of the effective mass tuning, which is demonstrated by the increasing slopes of the lines in plot 902 as the cavities become larger in size. While the examples depicted in FIG. 9B involve four square-shaped cavities arranged in a grid pattern around the center of the resonator element, it should be understood that the number, size, shape, and arrangement of the cavities may be varied in other examples, which may likewise vary the effect on TCF1ₜₒₜₐₗ. Further, while the examples depicted in FIG. 9B involve an SE/Lamé composite eigenmode having a single SE mode and a single Lamé mode, it should be understood that cavities may be similarly implemented in connection with various other composite eigenmode configurations, such as any of the composite eigenmode configurations described herein.

FIG. 9B depicts example results of tuning TCF2ₜₒₜₐₗ by adding cavities to one or more of the at least two sub-regions. Namely, plot 910 depicts the example effects on TCF2ₜₒₜₐₗ that result from adding cavities to an SE/Lamé composite eigenmode in the same or similar manner as described above in connection with FIG. 9A.

In some embodiments, the example methods described herein further comprise providing a third sub-region of the at least two sub-regions, wherein the third sub-region in isolation resonates with the first eigenmode and has the particular dopant type, the particular doping concentration, the first orientation with respect to the crystal axis, and the first TCFNₖ.

In some further embodiments, the example methods described herein further comprise providing a fourth sub-region and a fifth sub-region of the at least two sub-regions, wherein both the fourth sub-region in isolation and the fifth sub-region in isolation resonate with the first eigenmode and have the particular dopant type, the particular doping concentration, the first orientation with respect to the crystal axis, and the first TCFNₖ-

In some further embodiments, the example methods described herein further comprise providing a sixth sub-region, a seventh sub-region, an eighth sub-region, and a ninth sub-region of the at least two sub-regions, wherein the sixth sub-region in isolation, the seventh sub-region in isolation, the eighth sub-region in isolation, and the ninth sub-region in isolation resonate with the first eigenmode and have the particular dopant type, the particular doping concentration, the first orientation with respect to the crystal axis, and the first TCFNₖ.

In some embodiments, the respective resonance frequencies in isolation of the respective eigenmodes from the set of at least two eigenmodes are approximately equal.

In some embodiments, the set of at least two eigenmodes comprise at least two eigenmodes selected from the group consisting of (i) Lamé, (ii) face-shear, (iii) square-extensional, (iv) width-extensional, (v) length-extensional, (vi) Nth order annulus, (vii) breathing, (viii) wineglass, and (ix) higher order Lamé eigenmodes.

In some embodiments, the TCFNₖS of the at least two sub-regions in isolation combine to cause the TCFNₜₒₜₐₗ to be approximately equal to the TCFN_{desired}.

In some embodiments, the Nth order comprises the first order, and wherein TCFN_{desired} is approximately equal to 0 ppm/° C.

In some embodiments, the Nth order comprises the second order, and wherein TCFN_{desired} is approximately equal to 0 ppb/° C.².

In some embodiments, the Nth order comprises the first order, and wherein TCFN_{desired} is a nonzero value which, at least partly, compensates for the third order temperature coefficient of frequency of the composite eigenmode resonator element.

In some embodiments, each of the at least two sub-regions has the particular dopant type and the particular doping concentration.

### V. Non-Linear Effects Present in Composite Eigenmode Resonators

It is important to note that there exist limits to the linearity of the theoretical predictions provided by Equation 2. These limits are caused by modal distortions in the composite eigenmode present on the composite eigenmode resonator element 104 versus the eigenmode exhibited by each respective sub-region in isolation, whose TCFNₖS are used in Equation 2. The modal distortions can be quantified by observing the effective mass of an entire composite eigenmode resonator element 104 in comparison to the sum of effective masses of the n isolated sub-region eigenmodes. In an ideal case, if the two are equal, then all eigenmodes on the n sub-regions of the device are perfectly excited and the TCFNₜₒₜₐₗ value will perfectly match the results from Equation 2. However, if modal distortions are present, the effective mass of the actual composite eigenmode resonator element 104 will be lower than the sum of its parts (n sub-regions).

In fabricated composite eigenmode resonator devices 100, modal distortions will always be present, in part due to (i) non-ideal contact regions between one or more sub-regions and (ii) weakened coupling between the at least two sub-regions. Non-ideal contact regions will cause modal distortions in the composite eigenmode, as compared to the eigenmode exhibited by each respective sub-region in isolation. As these modal distortions increase, the composite eigenmode exhibited by the composite eigenmode resonator element 104 distances itself from being a combination of isolated eigenmodes and becomes one complex eigenmode whose TCFNₜₒₜₐₗ is difficult to predict analytically. Larger contact regions between two sub-regions will cause more modal distortions. Thus, it may be preferrable to minimize the contact regions between sub-regions. In some embodiments, the contact region may be defined by a line of intersection between two sub-regions. Schematic 912 provides an example of the line of intersection 914 in the contact region of a square-extensional (SE)/Lamé composite eigenmode. In some embodiments, minimizing the contact region between two sub-regions may involve reducing the line of intersection to be less than 10 μm. In other embodiments, this may involve reducing the line of intersection in the contact region of the two sub-regions to be less than 5 μm. Still in other embodiments, this may involve reducing the line of intersection in the contact region of the two sub-regions to be less than 1 μm. In some embodiments, the contact region may be defined by a bar between two sub-regions. In some embodiments, minimizing the contact region between two sub-regions may involve reducing the volume of the bar between two sub-regions to be less than 5% of the total volume of the composite eigenmode resonator element. In other embodiments, minimizing the contact region between two sub-regions may involve reducing the volume of the bar between two sub-regions to be less than 1% of the total volume of the composite eigenmode resonator element. Utilizing a bar between two sub-regions may be more advantageous than other methods when there are no convenient points of maximum displacement to form a sufficiently small contact region which minimizes the modal distortions due to non-ideal coupling. Image 446 provides an example of this scenario, where a sufficiently small contact region between the width-extensional and 3rd order Lamé eigenmode is not practically feasible.

Additionally, weaker coupling between sub-regions' eigenmodes will induce modal distortions. Weaker coupling will occur when performing resonance frequency tuning by scaling the dimensions of one or more sub-regions, as a result of increasing the difference between the resonance frequencies of the isolated eigenmodes. Increasing the difference between the resonance frequencies of the isolated eigenmodes will cause one eigenmode to dominate over the others. As per Equation 3, the displacement amplitude of a sub-region is directly tied to its effective mass. Thus, as an increasing percentage of the overall effective mass of the composite eigenmode resonator element 104 is represented by a dominant eigenmode, the modal distortions will be more prominent. In the extreme case, if the resonance frequency of the isolated eigenmodes is sufficiently far apart, the eigenmodes may completely decouple and the intended composite eigenmode could no longer be exhibited by the resonator element. In this extreme case, the one or more sub-regions may act as an anchor at a point of maximum displacement of the dominant eigenmode. This may cause large distortions from the pure eigenmodes which will cause the TCFNₜₒₜₐₗ to change unpredictably.

FIGS. 8A-C demonstrate the effect of increased modal distortions on the agreement between the theoretical and simulated TCFNₜₒₜₐₗ. As the dimensions of one or more sub-regions are scaled such that the resonance frequency of the one or more sub-regions are no longer equal, modal distortions increase and thus the difference between the simulated temperature coefficient of frequency and the analytically calculated temperature coefficient of frequency increase.

1. A MEMS resonator device, the device comprising:
a support structure;
a composite eigenmode resonator element comprising at least two sub-regions, wherein each of the at least two sub-regions in isolation is configured to resonate with a respective eigenmode from a set of at least two eigenmodes and has a respective Nth order temperature coefficient of frequency (TCFNₖ), wherein the at least two sub-regions includes a first sub-region and a second sub-region, wherein the first sub-region in isolation is configured to resonate with a first eigenmode from the set of at least two eigenmodes and has a particular dopant type, a particular doping concentration, a first orientation with respect to the crystal axis, and a first TCFNₖ, wherein the second sub-region in isolation is configured to resonate with a second eigenmode from the set of at least two eigenmodes and has the particular dopant type, the particular doping concentration, a second orientation with respect to the crystal axis, and a second TCFNₖ, and wherein either (i) the first TCFNₖ is greater than a desired Nth order temperature coefficient of frequency of the composite eigenmode resonator element (TCFN_{desired}) and the second TCFNₖ is less than TCFN_{desired} or (ii) the first TCFNₖ is less than TCFN_{desired} and the second TCFNₖ is greater than TCFN_{desired};
at least one anchor coupling the composite eigenmode resonator element to the support structure;
at least one driving electrode for actuation of the composite eigenmode resonator element; and
at least one sense electrode for sensing of the composite eigenmode resonator element.

2. The device according to claim 1, wherein the device is either (i) capacitively transduced or (ii) piezoelectrically transduced.

3. The device according to claim 1, wherein each of the at least two sub-regions is connected to at least one other sub-region by a contact region, wherein the contact region extends from points of maximum displacement amplitude.

4. The device according to claim 3, wherein each of the at least two sub-regions is connected to at least one other sub-region by a contact region, wherein the contact region is minimized such that modal distortions due to non-ideal coupling of the at least two sub-regions are minimized.

5. The device according to claim 4, wherein the contact region further comprises a bar, and wherein the volume of the bar is less than 5% of the volume of the composite eigenmode resonator element.

6. The device according to claim 1, wherein the at least two sub-regions further comprise a third sub-region, wherein the third sub-region in isolation resonates with the first eigenmode and has the particular dopant type, the particular doping concentration, the first orientation with respect to the crystal axis, and the first TCFNₖ.

7. The device according to claim 6, wherein the at least two sub-regions further comprise a fourth sub-region and a fifth sub-region, wherein both the fourth sub-region in isolation and the fifth sub-region in isolation resonate with the first eigenmode and have the particular dopant type, the particular doping concentration, the first orientation with respect to the crystal axis, and the first TCFNₖ.

8. The device according to claim 7, wherein the at least two sub-regions further comprise a sixth sub-region, a seventh sub-region, an eighth sub-region, and a ninth sub-region wherein the sixth sub-region in isolation, the seventh sub-region in isolation, the eighth sub-region in isolation, and the ninth sub-region in isolation resonate with the first eigenmode and have the particular dopant type, the particular doping concentration, the first orientation with respect to the crystal axis, and the first TCFNₖ.

9. The device according to claim 1, wherein the respective resonance frequencies in isolation of the respective eigenmodes from the set of at least two eigenmodes are approximately equal.

10. The device according to claim 1, wherein the set of at least two eigenmodes comprises two or more eigenmodes selected from the group consisting of (i) Lamé, (ii) face-shear, (iii) square-extensional, (iv) width-extensional, (v) length-extensional, (vi) Nth order annulus, (vii) breathing, (viii) wineglass, and (ix) higher order Lamé eigenmodes.

11. The device according to claim 1, wherein the TCFNₖS of the at least two sub-regions in isolation combine to cause an Nth order temperature coefficient of frequency of the composite eigenmode resonator element (TCFNₜₒₜₐₗ) to be approximately equal to the TCFN_{desired}.

12. The device according to claim 1, wherein the Nth order comprises the first order, and wherein TCFN_{desired} is approximately equal to 0 ppm/° C.

13. The device according to claim 1, wherein the Nth order comprises the second order, and wherein TCFN_{desired} is approximately equal to 0 ppb/° C.².

14. The device according to claim 1, wherein the Nth order comprises the first order, and wherein TCFN_{desired} is a nonzero value which, at least partly, compensates for a third order temperature coefficient of frequency of the composite eigenmode resonator element.

15. The device according to claim 1, wherein each of the at least two sub-regions has the particular dopant type and the particular doping concentration.

16. The device according to claim 1, wherein the composite eigenmode resonator element further comprises one or more cavities in one or more of the at least two sub-regions.

17. The device according to claim 1, wherein the effective mass of the composite eigenmode resonator element and a sum of the effective masses of each of the at least two sub-regions in isolation have a difference of <10%.

18. The device according to claim 1, wherein the device is configured to operate as either (i) an oscillator or (ii) a resonating sensor.

19. The device according to claim 1, wherein the device comprises at least one of single crystal silicon, silicon carbide, polycrystalline silicon, quartz, graphene, and polycrystalline diamond.

20. A method for designing a MEMS resonator device, the method comprising:
selecting a desired Nth order temperature coefficient of frequency (TCFN_{desired}) for a composite eigenmode resonator element, wherein the composite eigenmode resonator element comprises at least two sub-regions, wherein each of the at least two sub-regions is configured to resonate with a respective eigenmode from a set of at least two eigenmodes and is configured to have a respective Nth order temperature coefficient of frequency (TCFNₖ);
providing a first sub-region of the at least two sub-regions, wherein the first sub-region in isolation is configured to resonate with a first eigenmode from the set of at least two eigenmodes and has a particular dopant type, a particular doping concentration, and a first orientation with respect to the crystal axis, and wherein the first sub-region has a first TCFNₖ;
providing a second sub-region of the at least two sub-regions, wherein the second sub-region in isolation is configured to resonate with a second eigenmode from the set of at least two eigenmodes and has the particular dopant type, the particular doping concentration, and a second orientation with respect to the crystal axis, and wherein the second sub-region has a second TCFNₖ;
determining, for the composite eigenmode resonator element comprising the at least two sub-regions, an Nth order temperature coefficient of frequency of (TCFNₜₒₜₐₗ); and
tuning TCFNₜₒₜₐₗ such that it is approximately equal to TCFN_{desired},
wherein tuning TCFNₜₒₜₐₗ comprises altering at least one of the first or second TCFNₖ such that either (i) the first TCFNₖ is greater than TCFN_{desired} and the second TCFNₖ is less than TCFN_{desired} or (ii) the first TCFNₖ is less than TCFN_{desired} and the second TCFNₖ is greater than TCFN_{desired}.

21. The method according to claim 20, wherein tuning TCFNₜₒₜₐₗ such that it is approximately equal to TCFN_{desired} comprises one or more of (i) performing effective mass tuning (ii) performing resonance mode tuning or (iii) adding cavities to one or more of the at least two sub-regions, such that at least one of the first or second TCFNₖ is altered.

22. The method according to claim 20, further comprising providing a third sub-region of the at least two sub-regions, wherein the third sub-region in isolation resonates with the first eigenmode and has the particular dopant type, the particular doping concentration, the first orientation with respect to the crystal axis, and the first TCFNₖ.

23. The method according to claim 22, further comprising providing a fourth sub-region and a fifth sub-region of the at least two sub-regions, wherein both the fourth sub-region in isolation and the fifth sub-region in isolation resonate with the first eigenmode and have the particular dopant type, the particular doping concentration, the first orientation with respect to the crystal axis, and the first TCFNₖ.

24. The method according to claim 23, further comprising providing a sixth sub-region, a seventh sub-region, an eighth sub-region and a ninth sub-region of the at least two sub-regions, wherein the sixth sub-region in isolation, the seventh sub-region in isolation, the eighth sub-region in isolation, and the ninth sub-region in isolation resonate with the first eigenmode and have the particular dopant type, the particular doping concentration, the first orientation with respect to the crystal axis, and the first TCFNₖ.

25. The method according to claim 20, wherein the respective resonance frequencies in isolation of the respective eigenmodes from the set of at least two eigenmodes are approximately equal.

26. The method according to claim 20, wherein the set of at least two eigenmodes comprise two or more eigenmodes selected from the group consisting of (i) Lamé, (ii) face-shear, (iii) square-extensional, (iv) width-extensional, (v) length-extensional, (vi) Nth order annulus, (vii) breathing, (viii) wineglass, and (ix) higher order Lamé eigenmodes.

27. The method according to claim 20, wherein the TCFNₖS of the at least two sub-regions in isolation combine to cause the TCFNₜₒₜₐₗ to be approximately equal to the TCFN_{desired}.

28. The method according to claim 20, wherein the Nth order comprises the first order, and wherein TCFN_{desired} is approximately equal to 0 ppm/° C.

29. The method according to claim 20, wherein the Nth order comprises the second order, and wherein TCFN_{desired} is approximately equal to 0 ppb/° C.².

30. The method according to claim 20, wherein the Nth order comprises the first order, and wherein TCFN_{desired} is a nonzero value which, at least partly, compensates for a third order temperature coefficient of frequency of the composite eigenmode resonator element.

31. The method according to claim 20, wherein each of the at least two sub-regions has the particular dopant type and the particular doping concentration.
